(19) United States
(12) Patent Application Publication
(10) Pub. No.: US 2025/0048833 A1
(43) Pub. Date: Feb. 6, 2025

(54) METHOD FOR MANUFACTURING DISPLAY DEVICE, AND DISPLAY DEVICE

(71) Applicant: SHARP KABUSHIKI KAISHA, Sakai City, Osaka (JP)

(72) Inventor: Takahiro ADACHI, Sakai City, Osaka (JP)

(21) Appl. No.: 18/692,994

(22) PCT Filed: Nov. 5, 2021
(86) PCT No.: PCT/JP2021/040746

§ 371 Date: Mar. 18, 2024

(51) Int. Cl. H10K 59/12; H10K 59/38; H10K 102/00

(52) U.S. Cl. CPC H10K 59/1201; H10K 59/38; H10K 2102/331

(57) ABSTRACT

A method for manufacturing a display device includes forming a first sacrificing layer, forming a first recess in the first sacrificing layer, forming a first functional material layer at least in the first recess, and forming, by dissolving part or all of the first sacrificing layer, a first function layer obtained by patterning the first functional material layer. A contour of the first recess includes a first recessed figure that is a recessed figure in a plan view from above.

### TECHNICAL FIELD

The disclosure relates to a method for manufacturing a display device and a display device.

### BACKGROUND ART

A variety of flat panel displays have recently been developed, and in particular, a display device equipped with a quantum dot light emitting diode (QLED) or an organic light-emitting diode (OLED) as an electroluminescent element has attracted attention.

Examples of known methods for patterning a function layer in such a display device include methods using printing techniques such as ink-jet printing and letterpress printing and methods using photolithography techniques.

PTL 1 discloses, as for a method using ink-jet printing, a shape of an opening of a bank by which a filling property of ink into the opening of the bank can be controlled and mechanical strength of the bank is increased more than that of the related art.

PTL 2 discloses, as for a method using ink-jet printing, a line bank for forming an organic function layer having a uniform film thickness.

One of the methods using the photolithography techniques is a lift-off method. In the lift-off method, a sacrificing layer is patterned by a photolithography technique, a functional material layer is formed on the sacrificing layer, and the sacrificing layer is dissolved. The functional material layer on the sacrificing layer is peeled off (subjected to so-called “lift-off”) by dissolution, and a function layer with the functional material layer patterned is formed.

### CITATION LIST

### Patent Literature

PTL 1: WO 2011/058601A1
PTL 2: WO 2015/182096A1

### SUMMARY

### Technical Problem

A dissolving solution for dissolving the sacrificing layer in the lift-off method permeates the functional material layer and reaches the sacrificing layer. This causes the dissolving solution not to sufficiently reach the sacrificing layer, causing patterning failure of the function layer.

### Solution to Problem

To solve the above-described problem, a method for manufacturing a display device according to an aspect of the disclosure includes forming a first sacrificing layer, forming a first recess in the first sacrificing layer, forming a first functional material layer at least in the first recess, and forming, by dissolving part or all of the first sacrificing layer, a first function layer obtained by patterning the first functional material layer. A contour of the first recess includes a first recessed figure that is a recessed figure in a plan view from above.

The method for manufacturing a display device according to an aspect of the disclosure may be a method in which A is larger than 1.1 times B, where A is a peripheral length of the first recessed figure and B is a peripheral length of a protruding figure surrounding the first recessed figure and having a minimum area.

The method for manufacturing a display device according to an aspect of the disclosure may be a method in which the first recessed figure has an elongated shape, an outer shape of the first recessed figure includes a first contour portion, a first line segment connecting both ends of the first contour portion is parallel to a long axis of the first recessed figure, and D is larger than 1.1 times E, where D is a length of the first contour portion and E is a length of the first line segment.

The method for manufacturing a display device according to an aspect of the disclosure may be a method in which the first contour portion does not cross a center line parallel to the long axis of the first recessed figure.

The method for manufacturing a display device according to an aspect of the disclosure may be a method in which the first contour portion includes a fractal structure.

The method for manufacturing a display device according to an aspect of the disclosure may be a method in which a width in a direction along a short axis of the first recessed figure is regularly and repeatedly increased and decreased along the long axis of the first recessed figure.

The method for manufacturing a display device according to an aspect of the disclosure may be a method in which the contour of the first recess is an edge between an upper face and a side face of the first sacrificing layer, and the edge has an angular corner.

The method for manufacturing a display device according to an aspect of the disclosure may be a method in which the first recessed figure has line symmetry or rotation symmetry.

The method for manufacturing a display device according to an aspect of the disclosure may be a method in which in the forming the first recess, the first recess extends through the first sacrificing layer, and in the forming the first function layer, all the first sacrificing layer is dissolved.

The method for manufacturing a display device according to an aspect of the disclosure may be a method in which in the forming the first recess, a remaining portion of the first sacrificing layer remains below a bottom face of the first recess and in which in the forming the first function layer, a portion other than the remaining portion of the first sacrificing layer is dissolved, and thus the remaining portion of the first sacrificing layer remains.

The method for manufacturing a display device according to an aspect of the disclosure may be a method further including forming a pixel electrode and forming an edge cover covering an edge of the pixel electrode. The first recess may be larger than a corresponding opening of the edge cover in a plan view from above.

The method for manufacturing a display device according to an aspect of the disclosure may be a method further including forming a second sacrificing layer, forming a second recess in the second sacrificing layer, forming a second functional material layer at least in the second recess, and forming, by dissolving part or all of the second sacrificing layer, a second function layer obtained by patterning the second functional material layer. A contour of the second recess may include a second recessed figure in a plan view from above.

The method for manufacturing a display device according to an aspect of the disclosure may be a method in which a recessed portion of the first function layer faces a protruding portion of the second function layer in a plan view from above and in which a protruding portion of the first function layer faces a recessed portion of the second function layer in a plan view from above.

The method for manufacturing a display device according to an aspect of the disclosure may be a method in which the first function layer and the second function layer are in contact with each other in a plan view from above.

The method for manufacturing a display device according to an aspect of the disclosure may be a method in which the first function layer and the second function layer are separated from each other in a plan view from above.

The method for manufacturing a display device according to an aspect of the disclosure may be a method in which part of the first function layer and part of the second function layer overlap each other in a plan view from above.

The method for manufacturing a display device according to an aspect of the disclosure may be a method in which the first function layer includes a light-emitting layer.

The method for manufacturing a display device according to an aspect of the disclosure may be a method in which the first function layer includes a plurality of layers.

To solve the above-described problem, a display device according to an aspect of the disclosure includes a pixel electrode, an edge cover covering an edge of the pixel electrode, and a first function layer provided above the pixel electrode. A contour of the first function layer includes a recessed figure in a plan view from above, and at least part of an outer side face of the first function layer is separated from the edge cover.

### Advantageous Effects of Disclosure

An aspect of the disclosure can reduce patterning failure of the function layer.

### BRIEF DESCRIPTION OF DRAWINGS

FIG. 1 is a flowchart illustrating an example of a method for manufacturing a display device.

FIG. 2 is a schematic cross-sectional view illustrating an example of a configuration of a display region of a display device.

FIG. 3 is a schematic cross-sectional view illustrating an example of a configuration of a light-emitting element layer in the display region according to an embodiment of the disclosure.

FIG. 4 is a schematic plan view illustrating a shape of a light-emitting layer in the light-emitting element layer illustrated in FIG. 3.

FIG. 5 is a schematic plan view illustrating a shape of a light-emitting layer in a light-emitting element layer according to a comparative example.

FIG. 6 is a flowchart illustrating an example of a process of forming the light-emitting element layer illustrated in FIG. 3 and FIG. 4.

FIG. 7 is a flowchart illustrating an example of a process of forming the light-emitting layer illustrated in FIG. 3 and FIG. 4.

FIG. 8 is a cross-sectional view illustrating a process of forming the light-emitting element layer illustrated in FIG. 3 and FIG. 4.

FIG. 9 is a cross-sectional view illustrating the process of forming the light-emitting element layer illustrated in FIG. 3 and FIG. 4.

FIG. 10 is a plan view illustrating the process of forming the light-emitting element layer illustrated in FIG. 3 and FIG. 4.

FIG. 11 is a plan view illustrating a process of forming the light-emitting element layer according to the comparative example illustrated in FIG. 5.

FIG. 12 is a cross-sectional view illustrating the process of forming the light-emitting element layer illustrated in FIG. 3 and FIG. 4.

FIG. 13 is a partially enlarged cross-sectional view in which a portion surrounded by a box B in FIG. 12 is enlarged.

FIG. 14 is a cross-sectional view illustrating the process of forming the light-emitting element layer illustrated in FIG. 3 and FIG. 4.

FIG. 15 is a partially enlarged cross-sectional view in which a portion surrounded by a box B in FIG. 14 is enlarged.

FIG. 16 is a cross-sectional view illustrating the process of forming the light-emitting element layer illustrated in FIG. 3 and FIG. 4.

FIG. 17 is a cross-sectional view illustrating the process of forming the light-emitting element layer illustrated in FIG. 3 and FIG. 4.

FIG. 18 is a cross-sectional view illustrating the process of forming the light-emitting element layer illustrated in FIG. 3 and FIG. 4.

FIG. 19 is a cross-sectional view illustrating the process of forming the light-emitting element layer illustrated in FIG. 3 and FIG. 4.

FIG. 20 is a plan view illustrating one of various shape examples of the light-emitting layer according to the disclosure.

FIG. 21 is a plan view illustrating one of the various shape examples of the light-emitting layer according to the disclosure.

FIG. 22 is a plan view illustrating one of the various shape examples of the light-emitting layer according to the disclosure.

FIG. 23 is a plan view illustrating one of the various shape examples of the light-emitting layer according to the disclosure.

FIG. 24 is a plan view illustrating one of the various shape examples of the light-emitting layer according to the disclosure.

FIG. 25 is a plan view illustrating one of the various shape examples of the light-emitting layer according to the disclosure.

FIG. 26 is a plan view illustrating one of the various shape examples of the light-emitting layer according to the disclosure.

FIG. 27 is a plan view illustrating one of the various shape examples of the light-emitting layer according to the disclosure.

FIG. 28 is a plan view illustrating one of the various shape examples of the light-emitting layer according to the disclosure.

FIG. 29 is a plan view illustrating one of the various shape examples of the light-emitting layer according to the disclosure.

FIG. 30 is a plan view illustrating one of various arrangement examples of the light-emitting layer according to the disclosure.

FIG. 31 is a plan view illustrating one of the various arrangement examples of the light-emitting layer according to the disclosure.

FIG. 32 is a plan view illustrating one of the various arrangement examples of the light-emitting layer according to the disclosure.

FIG. 33 is a plan view illustrating one of the various arrangement examples of the light-emitting layer according to the disclosure.

FIG. 34 is a plan view illustrating one of the various arrangement examples of the light-emitting layer according to the disclosure.

FIG. 35 is a plan view illustrating one of the various arrangement examples of the light-emitting layer according to the disclosure.

FIG. 36 is a schematic cross-sectional view illustrating an example of a configuration of the light-emitting element layer in the display region according to an embodiment of the disclosure.

FIG. 37 is a schematic cross-sectional view illustrating an example of a configuration of the light-emitting element layer in the display region according to an embodiment of the disclosure.

FIG. 38 is a cross-sectional view illustrating a process of forming the light-emitting element layer illustrated in FIG. 37.

FIG. 39 is a cross-sectional view illustrating the process of forming the light-emitting element layer illustrated in FIG. 37.

FIG. 40 is a partially enlarged cross-sectional view in which a portion surrounded by a box B in FIG. 39 is enlarged.

FIG. 41 is a schematic cross-sectional view illustrating an example of a configuration of the light-emitting element layer in the display region according to an embodiment of the disclosure.

FIG. 42 is a flowchart illustrating an example of a process of forming the light-emitting element layer illustrated in FIG. 41.

FIG. 43 is a flowchart illustrating an example of a process of forming a hole transport layer and the light-emitting layer illustrated in FIG. 41.

FIG. 44 is a cross-sectional view illustrating the process of forming the light-emitting element layer illustrated in FIG. 41.

FIG. 45 is a cross-sectional view illustrating the process of forming the light-emitting element layer illustrated in FIG. 41.

FIG. 46 is a cross-sectional view illustrating the process of forming the light-emitting element layer illustrated in FIG. 41.

FIG. 47 is a schematic cross-sectional view illustrating an example of a configuration of the light-emitting element layer in the display region according to an embodiment of the disclosure.

FIG. 48 is a schematic plan view illustrating a shape and an arrangement of the light-emitting layer illustrated in FIG. 47.

FIG. 49 is a schematic plan view illustrating a modified example of a shape of a red light-emitting layer according to an embodiment of the disclosure.

FIG. 50 is a schematic cross-sectional view illustrating an example of a configuration of the light-emitting element layer in the display region according to an embodiment of the disclosure.

### DESCRIPTION OF EMBODIMENTS

### First Embodiment

### Method for Manufacturing Display Device and Configuration of the Same

In the following description, the “same layer” means a layer formed through the same process (film formation process), the “lower layer” means a layer formed through a process before that of the layer to be compared, and the “upper layer” means a layer formed through a process after that of the layer to be compared.

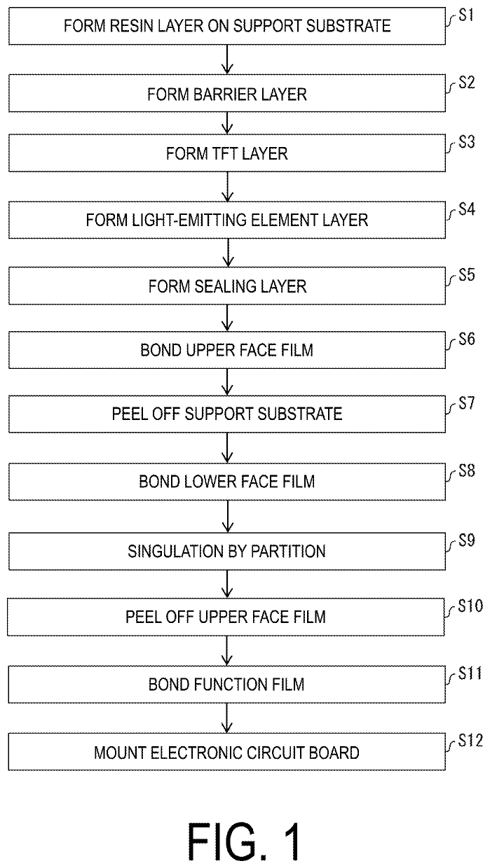

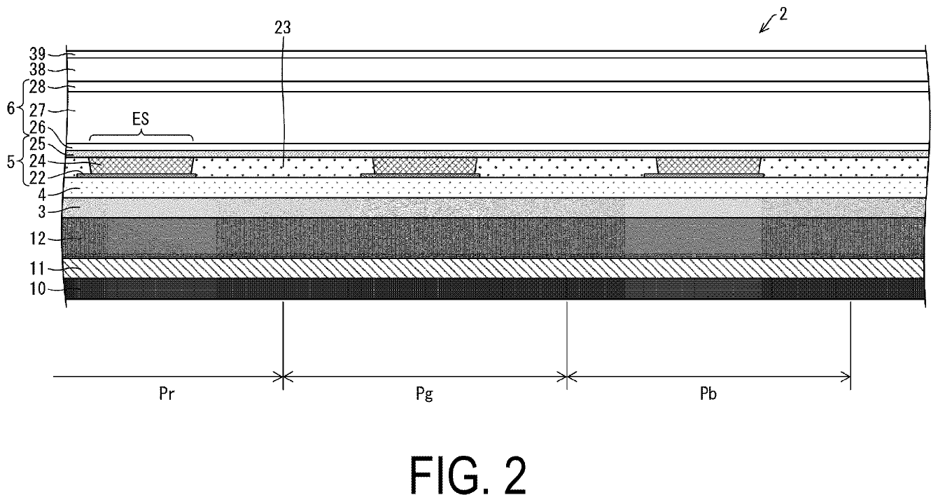

FIG. 1 is a flowchart illustrating an example of a method for manufacturing a display device 2. FIG. 2 is a schematic cross-sectional view illustrating an example of a configuration of a display region of the display device 2.

When the display device 2 that is flexible is manufactured, as illustrated in FIG. 1 and FIG. 2, first, a resin layer 12 is formed on a light-transmitting support substrate (for example, a mother glass) (step S1). Next, a barrier layer 3 is formed (step S2). Next, a thin film transistor layer 4 (TFT layer) is formed (step S3). Next, a light-emitting element layer 5 is formed (step S4). Next, a sealing layer 6 is formed (step S5). Next, an upper face film is bonded onto the sealing layer 6 with an adhesive layer therebetween (step S6).

Next, the support substrate is peeled off from the resin layer 12 through irradiation with laser light, or the like (step S7). Next, a lower face film 10 is bonded to a lower face of the resin layer 12 with an adhesive layer 11 therebetween (step S8). Next, a layered body including the lower face film 10, the adhesive layer 11, the resin layer 12, the barrier layer 3, the thin film transistor layer 4, the light-emitting element layer 5, and the sealing layer 6 is divided together with the upper face film to obtain a plurality of individual pieces (step S9). Next, the upper face film is peeled off from each of the obtained individual pieces (step S10), and a function film 39 is bonded onto the sealing layer 6 of each of the obtained individual pieces with an adhesive layer 38 therebetween (step S11). Next, an electronic circuit board (for example, an IC chip and an FPC) is mounted on a portion (terminal portion) of a frame region (non-display region) surrounding a display region where a plurality of subpixels are formed (step S12). Note that steps S1 to S12 are executed by a display device manufacturing apparatus (including a film formation apparatus that executes the process from steps S1 to S5).

The light-emitting element layer 5 includes a pixel electrode 22 positioned in a layer higher than the thin film transistor layer 4, an edge cover 23 that has insulating properties and that covers an edge of the pixel electrode 22, an active layer 24 that is an ElectroLuminescence (EL) layer and that is positioned in a layer higher than the edge cover 23, and a common electrode 25 positioned in a layer higher than the active layer 24.

For each subpixel, a light-emitting element ES (electroluminescent element) that includes the pixel electrode 22 having an island shape, the active layer 24, and the common electrode 25 and is a QLED or an OLED is formed in the light-emitting element layer 5, and a subpixel circuit that controls the light-emitting element ES is formed in the thin film transistor layer 4.

The sealing layer 6 is transparent, and includes an inorganic sealing film 26 that covers the common electrode 25, an organic buffer film 27 positioned in a layer higher than the inorganic sealing film 26, and an inorganic sealing film 28 positioned in a layer higher than the organic buffer film 27. The sealing layer 6 covering the light-emitting element layer 5 inhibits foreign matters such as water and oxygen from permeating the light-emitting element layer 5.

The flexible display device has been described above, but when the display device is manufactured as a non-flexible display device, because formation of a resin layer and replacement of a base material are typically not required, the process proceeds to step S9 after the layering process on the glass substrate of steps S2 to S5 is executed. Furthermore, when a non-flexible display device is manufactured, a light-transmitting sealing member may be caused to adhere using a sealing adhesive instead of or in addition to forming the sealing layer 6, under a nitrogen atmosphere. The light-transmitting sealing member can be formed from glass, plastic, or the like, and preferably has a recessed shape.

### Configuration of Light-Emitting Element Layer

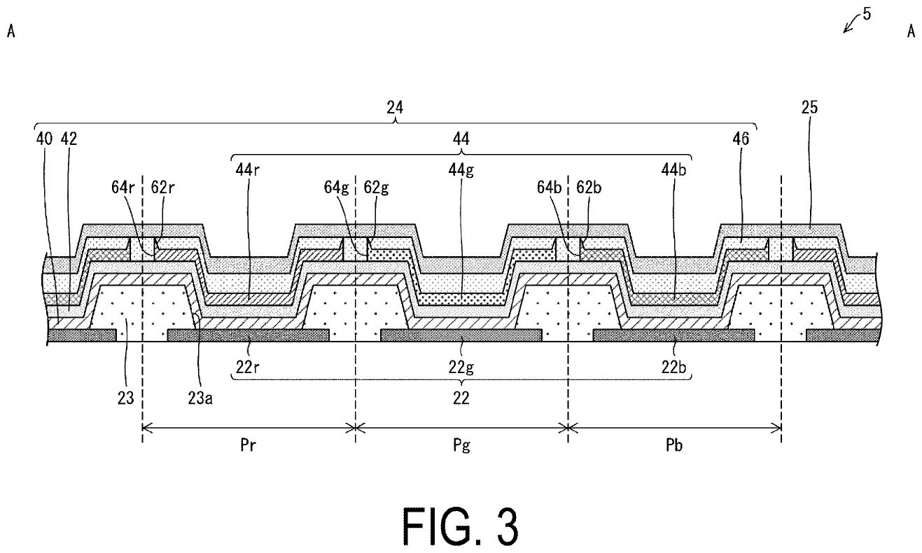

FIG. 3 is a schematic cross-sectional view illustrating an example of a configuration of the light-emitting element layer 5 in the display region according to an embodiment of the disclosure.

As illustrated in FIG. 3, a red subpixel Pr, a green subpixel Pg, and a blue subpixel Pb are provided in the display region of the display device 2. For example, in the display device 2, one pixel is formed by using the red subpixel Pr, the green subpixel Pg, and the blue subpixel Pb.

As illustrated in FIG. 3, the light-emitting element layer 5 includes the pixel electrode 22, the edge cover 23 covering the edge of the pixel electrode 22, the active layer 24, and the common electrode 25.

The pixel electrode 22 includes a red subpixel electrode 22r provided in the red subpixel Pr, a green subpixel electrode 22g provided in the green subpixel Pg, and a blue subpixel electrode 22b provided in the blue subpixel Pb. The common electrode 25 is commonly provided across the red subpixel Pr, the green subpixel Pg, and the blue subpixel Pb. In an example illustrated in FIG. 3, the pixel electrode 22 is an anode and the common electrode 25 is a cathode. In addition to this, a configuration in which the pixel electrode is a cathode and the common electrode is an anode is also included in the scope of the disclosure.

As an example, the active layer 24 includes a hole injection layer 40, a hole transport layer 42, a light-emitting layer 44, and an electron transport layer 46 in this order from the pixel electrode 22 toward the common electrode 25. The active layer 24 does not need to include one or more of the hole injection layer 40, the hole transport layer 42, and the electron transport layer 46. The active layer 24 may further include one or more layers such as an electron shielding layer, a charge generating layer, an electron injection layer, and a hole shielding layer.

Each of the hole injection layer 40, the hole transport layer 42, and the electron transport layer 46 is commonly provided across the red subpixel Pr, the green subpixel Pg, and the blue subpixel Pb.

Each of the hole injection layer 40 and the hole transport layer 42 contains a hole transport material. The hole transport material may be, for example, a non-photosensitive material such as NiO, CuI, Cu₂O, CoO, Cr₂O₃, or TiO₂, or a photosensitive material such as OPTO, QUPD, or X-F6-TAPC.

The electron transport layer 46 contains an electron transport material. Examples of the electron transport material include ZnO, ZnS, ZrO, MgZnO, AlZnO, and TiO₂.

The light-emitting layer 44 includes a red light-emitting layer 44r (first function layer), a green light-emitting layer 44g (second function layer), and a blue light-emitting layer 44b (third function layer).

The red light-emitting layer 44r is provided above the red subpixel electrode 22r and contains a light-emitting material that emits red light. Similarly, the green light-emitting layer 44g is provided above the green subpixel electrode 22g and contains a light-emitting material that emits green light. The blue light-emitting layer 44b is provided above the blue subpixel electrode 22b and contains a light-emitting material that emits blue light. Each light-emitting material may be a quantum dot, or an organic light-emitting material.

The quantum dot may be a core type, a core-shell type, or a core-multishell type. Examples of materials of the core-shell type quantum dots include CdSe/CdS, CdSe/ZnS, CdTe/CdS, InP/ZnS, GaP/ZnS, Si/ZnS, InN/GaN, InP/CdSSe, InP/ZNSeTe, GaInP/ZnSe, GaInP/ZnS, Si/AlP, InP/ZnSTe, GaInP/ZnSTe, and GaInP/ZnSSe. Here, the material described before the slash (/) indicates a material constituting a core layer of the core-shell type quantum, and the material described after/indicates a material constituting a shell layer of the core-shell type quantum.

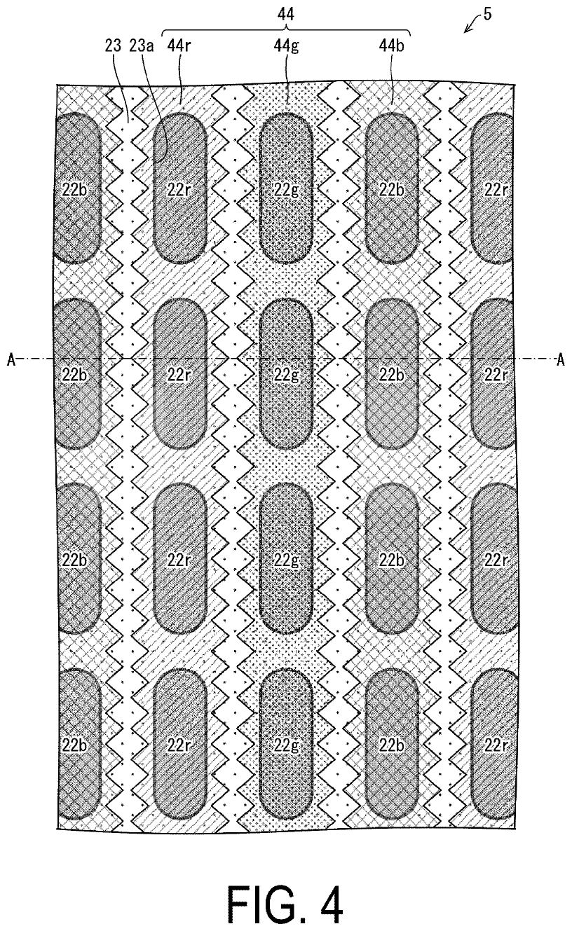

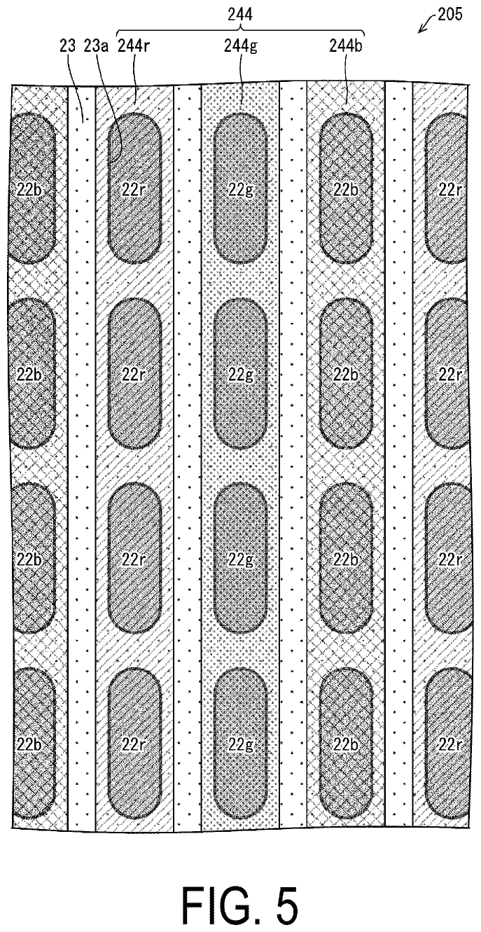

FIG. 4 is a schematic plan view illustrating a shape of the light-emitting layer 44 in the light-emitting element layer 5 illustrated in FIG. 3. FIG. 5 is a schematic plan view illustrating a shape of a light-emitting layer 244 in a light-emitting element layer 205 according to a comparative example.

The light-emitting element layer 205 according to the comparative example is substantially equivalent to the light-emitting element layer 5 according to the disclosure except that a shape of the light-emitting layer 244 according to the comparative example in a plan view is different from a shape of the light-emitting layer 44 according to the disclosure in a plan view. To facilitate understanding of the disclosure, FIG. 4 and FIG. 5 illustrate only the edge cover 23 and openings 23a thereof, the light-emitting layers 44 and 244, and the pixel electrodes 22 exposed from the openings 23a of the edge cover 23, and omit the other constituent elements. FIG. 3 corresponds to a cross-sectional view taken along AA in FIG. 4.

In the example illustrated in FIG. 4, in a plan view from above, a shape of the red light-emitting layer 44r according to the disclosure is a recessed figure (first recessed figure), and a shape of the opening 23a of the edge cover 23 corresponding to the red subpixel electrode 22r (that is, corresponding to the red light-emitting layer 44r) is a protruding figure. The red light-emitting layer 44r is larger than the corresponding opening 23a, which prevents electric field concentration and short-circuiting in the red subpixel Pr. The opening 23a of the edge cover 23 is a light-emitting region that emits light to the outside in the display device 2, and a region where the edge cover 23 is formed is a non-light-emitting region that is not intended to emit light to the outside. Additionally, a region other than the light-emitting region is a non-light-emitting region.

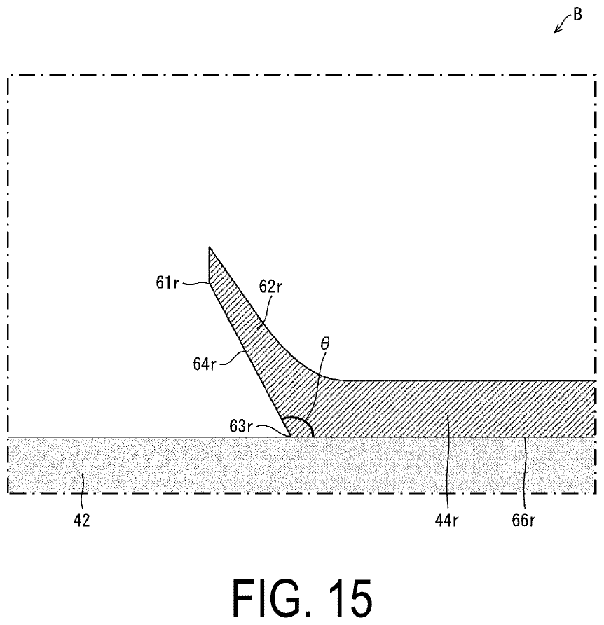

Further, as illustrated in FIG. 3 and FIG. 4, a contour of the red light-emitting layer 44r is formed in the non-light-emitting region in a plan view. On the contour of the red light-emitting layer 44r, a lower layer of the red light-emitting layer 44r is the hole transport layer 42. As illustrated in FIG. 3, a part (concretely, an upper portion) of the edge cover 23 includes a planar face substantially parallel to the substrate, the hole transport layer 42 formed above the planar face of the edge cover 23 also includes a planar face, and the contour of the red light-emitting layer 44r is formed on the planar face of the hole transport layer 42 formed in a lower layer of the contour of the red light-emitting layer 44r. When the contour of the red light-emitting layer 44r is formed on such a planar face, a space between an outer side face (for example, a face 64r in FIG. 15) of the red light-emitting layer 44r, which will be described later, and the edge cover 23 becomes large and stable, and etching of the sacrificing layer by using a developing solution is easily stabilized, which is preferable.

Similarly, in a plan view from above, a shape of the green light-emitting layer 44g according to the disclosure is a recessed figure (second recessed figure), and a shape of the opening 23a of the edge cover 23 corresponding to the green subpixel electrode 22g (that is, corresponding to the green light-emitting layer 44g) is a protruding figure. The green light-emitting layer 44g is larger than the corresponding opening 23a, which prevents electric field concentration and short-circuiting in the green subpixel Pg.

Similarly, in a plan view from above, a shape of the blue light-emitting layer 44b according to the disclosure is a recessed figure (third recessed figure), and a shape of the opening 23a of the edge cover 23 corresponding to the blue subpixel electrode 22b (that is, corresponding to the blue light-emitting layer 44b) is a protruding figure. The blue light-emitting layer 44b is larger than the corresponding opening 23a, which prevents electric field concentration and short-circuiting in the blue subpixel Pb.

As illustrated in FIG. 5, on the other hand, each of contours of a red light-emitting layer 244r, a green light-emitting layer 244g, and a blue light-emitting layer 244b according to the comparative example is a protruding figure larger than the corresponding opening 23a of the edge cover 23 in a plan view from above.

The “protruding figure” means a figure in which a line segment connecting any two points included in the inside or the boundary of the figure does not pass through the outside of the figure. The “recessed figure” means any figure other than the protruding figure. That is, the “recessed figure” is a figure in which a line segment connecting two points included in the inside or the boundary of the figure can pass through the outside of the figure. In the disclosure, a “figure” means a two-dimensional figure, unless otherwise stated.

In the disclosure, both a configuration in which the shape of the formation region of the light-emitting layer is a recessed figure and a configuration in which the shape of the non-formation region of the light-emitting layer is a recessed figure are expressed as “the contour of the light-emitting layer 44 includes a recessed figure”. Similarly, both a configuration in which the shape of the formation region of the recess is a recessed figure and a configuration in which the shape of the non-formation region of the recess is a recessed figure are expressed as “the contour of the recess includes a recessed figure”.

Compared with the protruding figure, the recessed figure tends to have a larger rate of a peripheral length to an area. Thus, compared with the light-emitting layer 244 according to the comparative example, the light-emitting layer 44 according to the disclosure has a large rate of a peripheral length of the light-emitting layer 44 to an area of the light-emitting layer 44 (or an area of a region of the display region where the light-emitting layer 44 is not formed, or an area of the entire display region). The peripheral length of the light-emitting layer 44 is a length of the contour of the light-emitting layer 44 in a plan view of the light-emitting layer 44 from above.

A preferable shape of the light-emitting layer 44 according to the disclosure will be described in detail later.

### Process of Forming Light-Emitting Element Layer

Hereinafter, the process of forming the light-emitting element layer 5 (step S4) illustrated in FIG. 3 and FIG. 4 will be described.

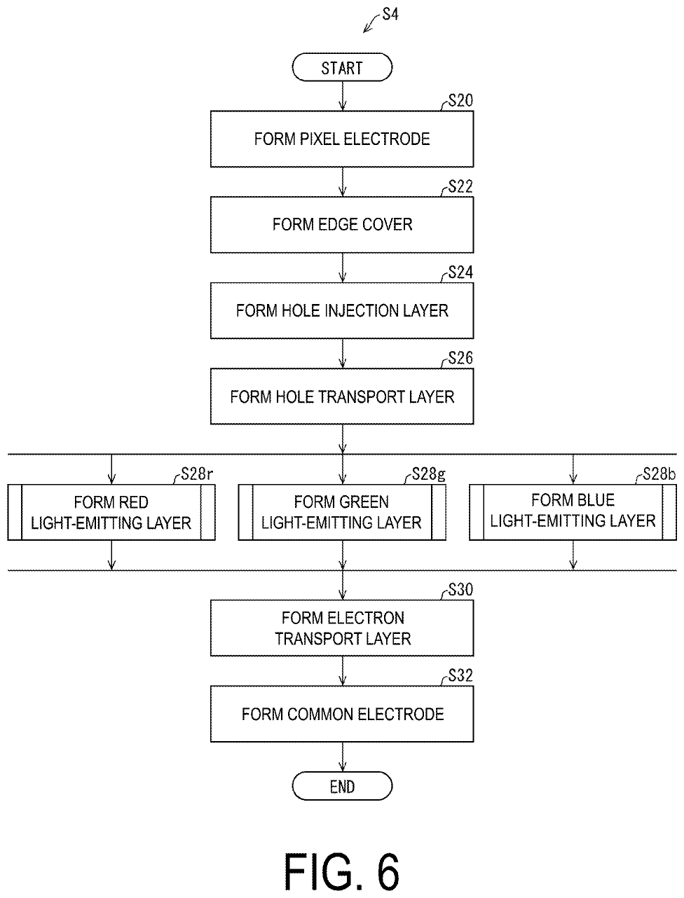

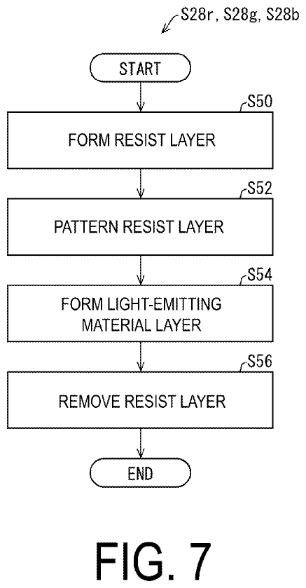

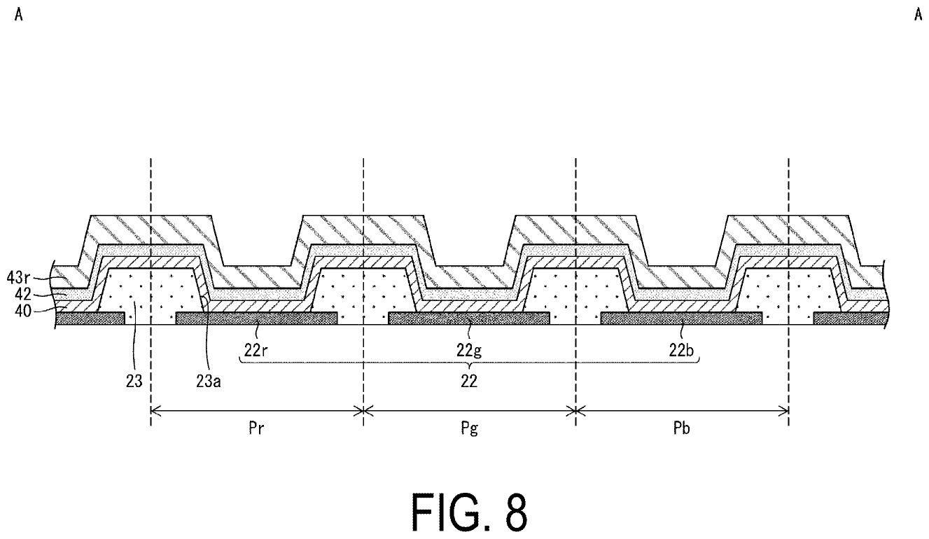

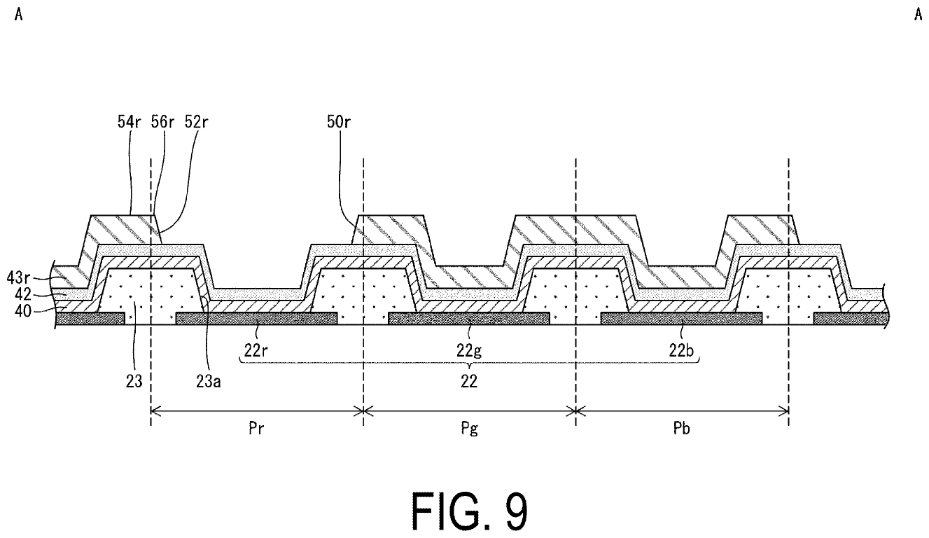

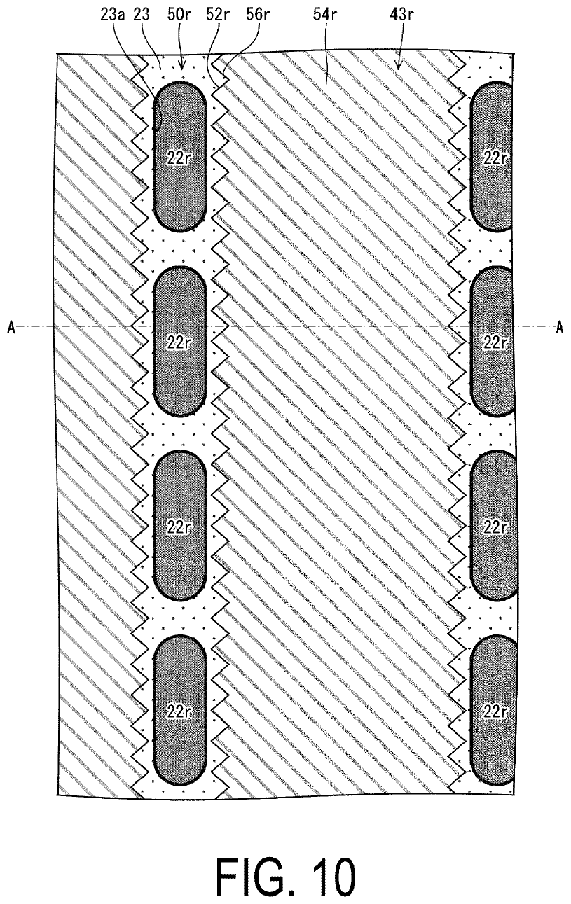

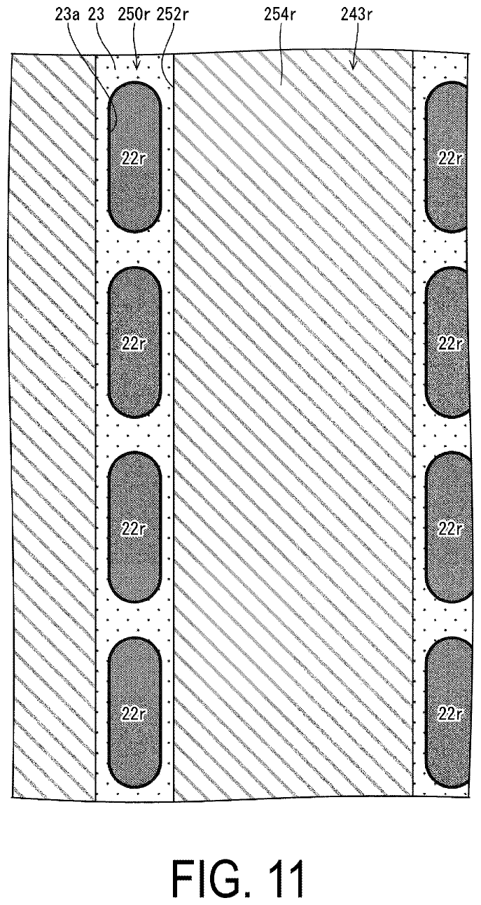

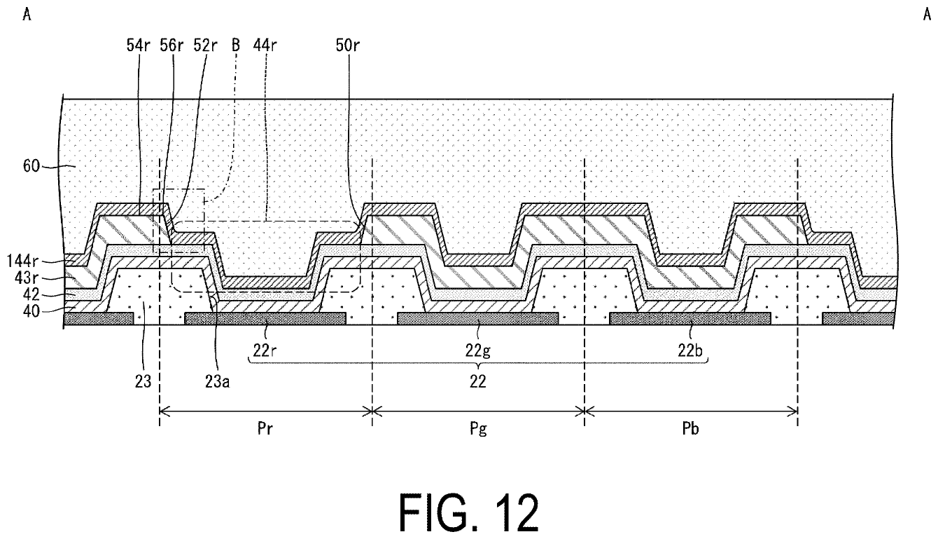

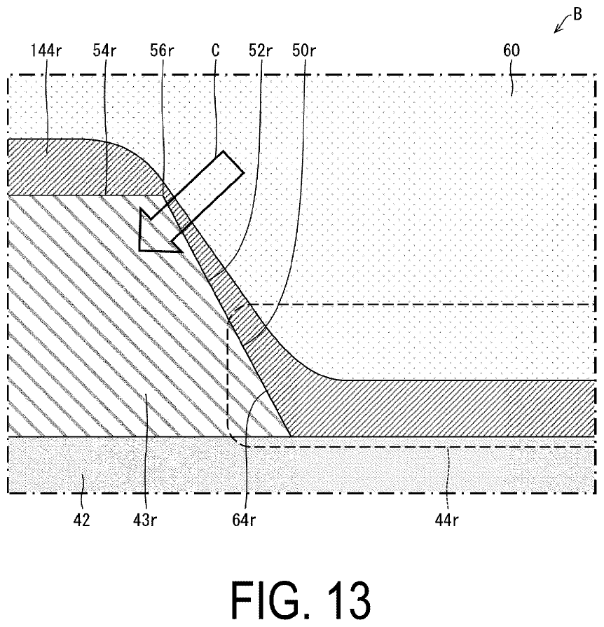

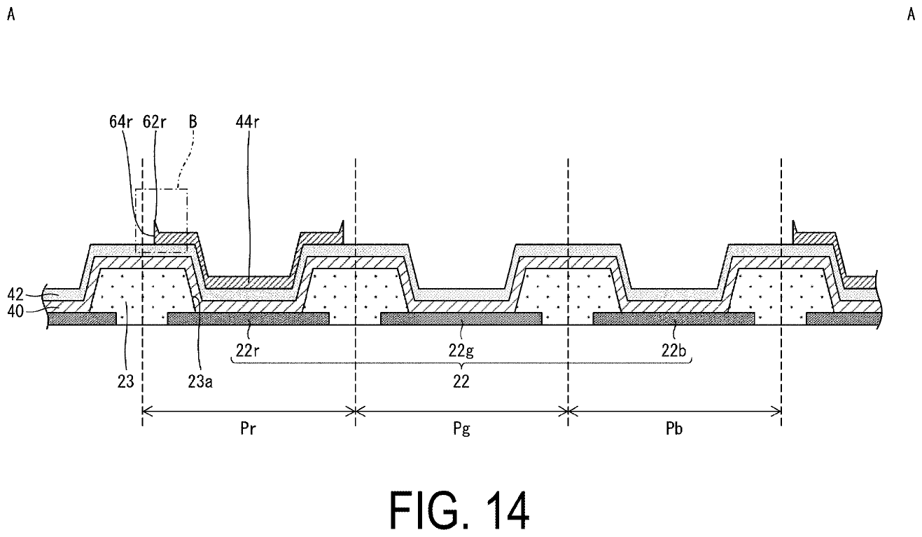

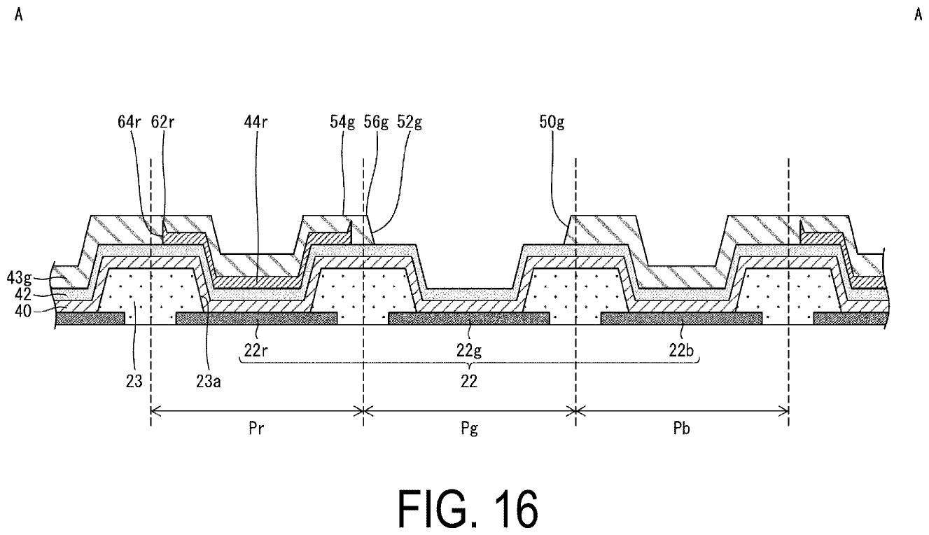

FIG. 6 is a flowchart illustrating an example of the process of forming the light-emitting element layer 5 (step S4) illustrated in FIG. 3 and FIG. 4. FIG. 7 is a flowchart illustrating an example of the process of forming the light-emitting layer 44 (steps S28r, S28g, and S28b) illustrated in FIG. 3 and FIG. 4. FIG. 8 and FIG. 9, FIG. 12, FIG. 14, and FIG. 16 to FIG. 19 are cross-sectional views illustrating the process of forming the light-emitting element layer 5 illustrated in FIG. 3 and FIG. 4. FIG. 10 is a plan view illustrating the process of forming the light-emitting element layer 5 illustrated in FIG. 3 and FIG. 4. FIG. 11 is a plan view illustrating the process of forming the light-emitting element layer 205 of the comparative example illustrated in FIG. 6. FIG. 13 is a partially enlarged cross-sectional view in which a portion surrounded by a box B in FIG. 12 is enlarged. FIG. 15 is a partially enlarged cross-sectional view in which a portion surrounded by a box B in FIG. 14 is enlarged. FIG. 9 corresponds to a cross-sectional view taken along AA in FIG. 10.

As illustrated in FIG. 6, first, the pixel electrode 22 is formed (step S20), the edge cover 23 that covers the edge of the pixel electrode 22 is formed (step S22), the hole injection layer 40 is formed (step S24), and the hole transport layer 42 is formed (step S26). Subsequently, formation of the red light-emitting layer 44r (step S28r), formation of the green light-emitting layer 44g (step S28g), and formation of the blue light-emitting layer 44b (step S28b) are performed in a freely selected order. Next, the electron transport layer 46 is formed (step S30), and the common electrode 25 is formed (step S32). This forms the light-emitting element layer 5 illustrated in FIG. 3 and FIG. 4.

Hereafter, formation of the red light-emitting layer 44r (step S28r), formation of the green light-emitting layer 44g (step S28g), and formation of the blue light-emitting layer 44b (step S28b) are performed in a freely selected order. Note that although an example in which the entire light-emitting layer 44 is formed by a lift-off method will be described below, the scope of the disclosure is not limited thereto. Also, although an example in which a lift-off template for patterning the function layer is formed from a photoresist layer will be described, the scope of the disclosure is not limited thereto. For example, a template layer not including a photoresist may be formed, a photoresist layer may be formed on the template layer, the photoresist layer may be patterned using a photolithography technique, and the template layer may be patterned by etching using the photoresist layer as a protective mask. In this case, the lift-off template is formed from the template layer. The manufacturing method in which at least one of the light-emitting layers 44 is formed by a lift-off method and the configuration obtained as a result thereof are within the scope of the disclosure.

### Process of Forming Red Light-Emitting Layer

The process of forming the red light-emitting layer 44r (step S28r) illustrated in FIG. 3 and FIG. 4 will be described below.

As illustrated in FIG. 7 and FIG. 8, first, a first photoresist layer 43r (first sacrificing layer) is formed on the entire display region including the red subpixel Pr, the green subpixel Pg, and the blue subpixel Pb (step S50). In step S50, a liquid containing a photoresist and a solvent is applied onto the hole transport layer 42 and prebaking is performed. The application may be performed by a freely selected method such as a spin coating method, a slit coating method, a bar coating method, or a spraying method. Prebaking may be performed by placing the substrate on a hot plate or in an oven, or may be alternatively performed by vacuum drying. The photoresist may be positive-working or negative-working. A positive-working photoresist (hereinafter referred to as a “positive resist”) is insoluble in a developing solution in an unexposed state, and is solubilized in the developing solution by exposure. A negative-working photoresist (hereinafter referred to as a “negative resist”) is soluble in a developing solution in an unexposed state, and is insolubilized in the developing solution by exposure. The photoresist may be any of acrylic-based, novolac-based, rubber-based, styrene-based, and epoxy-based photoresists. Hereinafter, for simplification of description, an example in which the first photoresist layer 43r includes a positive resist will be described.

Light-emitting materials such as quantum dots and organic electroluminescent materials are likely to degrade. In particular, when the light-emitting material is exposed to light in an environment containing oxygen and/or moisture, the excited light-emitting material activates oxygen or moisture, and the active species may degrade the light-emitting material itself or surrounding materials. Thus, it is desirable that at least the exposure process be performed in a vacuum or an inert atmosphere. The inert atmosphere is an inert gas such as a dry nitrogen gas or a noble gas.

As illustrated in FIG. 9 and FIG. 10, next, the first photoresist layer 43r is patterned using a photolithography technique (step S52). To be specific, the first photoresist layer 43r is exposed using a mask, and the first photoresist layer 43r is developed using a developing solution. An optical opening provided in the mask is arranged at a position where the red light-emitting layer 44r is to be formed in the future since the first photoresist layer 43r contains a positive resist. For the exposure, any of ultraviolet rays, electron beams, laser light, and the like may be used. Then, a portion of the first photoresist layer 43r corresponding to a position where the red light-emitting layer 44r is to be formed in the future is exposed to light, becomes soluble in the developing solution, and is removed. On the other hand, a portion of the first photoresist layer 43r that does not correspond to a position where the red light-emitting layer 44r is to be formed in the future is not exposed to light and remains insoluble in the developing solution. The developing solution may be, for example, an alkaline solution containing a base such as potassium hydroxide (KOH) and TetraMethylAmmonium Hydroxide (TMAH), or an organic solvent such as Propylene Glycol Monomethyl Ether Acetate (PGMEA), acetone, or IsoPropyl Alcohol (IPA).

As a result of the patterning, a first recess 50r is formed in the first photoresist layer 43r. The first recess 50r is formed at a position where the red light-emitting layer 44r is to be formed in the future. The first recess 50r according to the present embodiment extends through the first photoresist layer 43r, and the hole transport layer 42 is exposed from a bottom face of the first recess 50r. In a plan view, a shape of the first recess 50r is equivalent to the shape of the red light-emitting layer 44r to be formed in the future, and thus, a contour of the first recess 50r includes a recessed figure (first recessed figure).

To prevent electric field concentration and short-circuiting as described above, it is preferable that the red light-emitting layer 44r be larger than the corresponding opening 23a of the edge cover 23. Thus, it is preferable that the first recess 50r be larger than the corresponding opening 23a of the edge cover 23 in a plan view from above.

The shape of the first recess 50r preferably has regularity and/or symmetry so that etching of the first photoresist layer 43r by the developing solution is stabilized. Here, the symmetry may be line symmetry or rotation symmetry. When the first recess 50r has a regular and/or symmetrical shape, a flow of the developing solution in the first recess 50r is also regular and/or symmetrical. Thus, etching by the developing solution is likely to be isotropically performed, and etching conditions are likely to be stable.

As illustrated in FIG. 11, on the other hand, when the red light-emitting layer 244r of the comparative example illustrated in FIG. 5 is formed, a shape of a recess 250r formed in a photoresist layer 243r is a protruding figure. As described above, a recessed figure tends to have a larger rate of a peripheral length to an area than that of a protruding figure. Thus, a length of an edge 56r of the first recess 50r according to the disclosure is larger than a length of an edge of the recess 250r according to the comparative example.

In the disclosure, the “edge of the recess” is an edge between an upper face of the sacrificing layer in which the recess is formed and a side face of the sacrificing layer corresponding to the recess. For example, the edge 56r of the first recess 50r according to the disclosure is formed between an upper face 54r of the first photoresist layer 43r and a side face 52r of the first recess 50r.

As illustrated in FIG. 12, next, a red light-emitting material layer 144r (first functional material layer) is formed at least in the first recess 50r (step S54). The red light-emitting material layer 144r may be formed by any method such as coating, vapor deposition, or sputtering. Normally, the red light-emitting material layer 144r is formed over the entire display region. The red light-emitting material layer 144r preferably contains a quantum dot so that a stripper 60 can permeate the red light-emitting material layer 144r and easily reach the first photoresist layer 43r in a post process. Thus, the red light-emitting material layer 144r is preferably formed by coating.

In the case of the coating, in step S56, a liquid containing a light-emitting material is applied onto the entire display region from above the first photoresist layer 43r and prebaking is performed. The application may be performed by any method such as a spin coating method, a slit coating method, or a bar coating method. Prebaking may be performed by placing the substrate on a hot plate or in an oven, or may be alternatively performed by vacuum drying. The liquid tends to spread along the first photoresist layer 43r due to surface tension. The liquid in the first recess 50r is drawn toward the side face 52r of the first recess 50r due to surface tension. For this reason, the shape of the first recess 50r is preferably a shape having high regularity and/or high symmetry so that the liquid uniformly spreads in the first recess 50r. When the first recess 50r has a regular and/or symmetrical shape, the surface tension acting on the liquid in the first recess 50r is also regular and/or symmetrical, so that the surface tension tends to be balanced with the liquid evenly spreading.

As described above, since the length of the edge 56r of the first recess 50r according to the disclosure is large, the effect that the side face 52r draws the liquid is large. Thus, the liquid is easily filled into the first recess 50r, and the liquid in the first recess 50r easily covers the bottom face of the first recess 50r. On the other hand, since an edge and a side face 252r of the recess 250r according to the comparative example illustrated in FIG. 11 are small, a problem that the liquid filled in the recess 250r is insufficient and a problem that part of a bottom face of the recess 250r is not covered with the liquid are likely to occur.

Next, all of the first photoresist layer 43r is removed using the stripper 60 (step S56). The stripper 60 is a developing solution for the first photoresist layer 43r or a solvent in which the first photoresist layer 43r is soluble regardless of whether the first photoresist layer 43r is exposed to light or not. The solvent is, for example, an organic solvent such as Propylene Glycol Monomethyl Ether Acetate (PGMEA), acetone, or IsoPropyl Alcohol (IPA).

When the stripper 60 is a developing solution, the stripper 60 is applied onto the red light-emitting material layer 144r after the entire first photoresist layer 43r is exposed to light. On the other hand, when the stripper 60 is an organic solvent, the stripper 60 is applied onto the red light-emitting material layer 144r without exposing the first photoresist layer 43r to light.

When the entire first photoresist layer 43r is exposed to light, it is preferable to perform exposure by using a mask to prevent deterioration of a portion of the red light-emitting material layer 144r that is to serve as the red light-emitting layer 44r. In the mask, a light blocking portion is provided at a position where the red light-emitting layer 44r is to be formed in the future, and an optical opening is provided at the other position. Alternatively, when the red light-emitting material layer 144r is not substantially deteriorated due to exposure, it is preferable to perform exposure without using a mask to simplify the manufacturing process.

As illustrated in FIG. 13, the red light-emitting material layer 144r is thin at the edge 56r of the first recess 50r and in the vicinity thereof (hereinafter referred to as “in the vicinity of the edge 56r”). In some cases, the red light-emitting material layer 144r may be discontinuous in the vicinity of the edge 56r. Thus, as indicated by an arrow C, the stripper 60 easily reaches the first photoresist layer 43r in the vicinity of the edge 56r.

The edge 56r of the first recess 50r is an edge between the upper face 54r and the side face 52r of the first photoresist layer 43r. When the edge 56r has an angular corner, the red light-emitting material layer 144r tends to be thin in the vicinity of the edge 56r and tends to be easily disconnected as compared with a case where the edge 56r has a rounded corner. Thus, the edge 56r of the first recess 50r preferably has an angular corner.

As illustrated in FIG. 14, when the stripper 60 is removed in step S56, the first photoresist layer 43r dissolved in the stripper 60 is removed together. Furthermore, a portion of the red light-emitting material layer 144r formed on the first photoresist layer 43r is also removed together. As a result, the red light-emitting material layer 144r is patterned, and a portion of the red light-emitting material layer 144r formed in the first recess 50r remains as the red light-emitting layer 44r.

As illustrated in FIG. 15, an end portion of the red light-emitting layer 44r usually includes a burr portion 62r. The burr portion 62r is derived from a portion of the red light-emitting material layer 144r that has crept up the side face 52r of the first photoresist layer 43r. In addition, at least part of the outer side face of the red light-emitting layer 44r is the face 64r that has been in contact with the side face 52r of the first photoresist layer 43r. The face 64r that has been in contact with the first photoresist layer 43r is separated from the edge cover 23. Thus, at least part of the outer side face of the red light-emitting layer 44r is separated from the edge cover 23.

When the lift-off method is used, the first photoresist layer 43r that serves as the sacrificing layer is dissolved to peel off the red light-emitting layer 44r formed on the sacrificing layer, and a region where the red light-emitting layer 44r and the sacrificing layer to be dissolved have been in contact with each other becomes the outer side face of the red light-emitting layer 44r. In the red light-emitting layer 44r left by the peeling, an edge is formed at least part of the surface of the red light-emitting layer 44r that is not in contact with the edge cover 23. For example, an edge portion of a surface of the red light-emitting layer 44r that is on the edge cover 23 and is not in contact with the hole transport layer 42 is referred to as a first edge 61r, and a contour of a lower face 66r at which the red light-emitting layer 44r is in contact with the hole transport layer 42 is referred to as a second edge 63r. At this time, the outer side face of the red light-emitting layer 44r is a face sandwiched between the first edge 61r and the second edge 63r. In addition, although the burr portion 62r may be broken during manufacturing, an edge of a face formed after the breakage may serve as a first edge, and a face sandwiched between the first edge and the second edge 63r may serve as an outer side face of the red light-emitting layer 44r. When the red light-emitting layer is formed by the ink-jet method, the surface of the red light-emitting layer that is not in contact with the hole transport layer 42 is entirely smooth and has no edge, so that no outer side face is formed.

Moreover, the red light-emitting layer 44r is formed such that, for example, an angle θ between the outer side face and the lower face 66r of the red light-emitting layer 44r is equal to or more than 90 degrees and less than 180 degrees. At this time, the smaller the angle θ is, the larger an area of the upper face of the first photoresist layer 43r is. Thus, the first photoresist layer 43r is open to the stripper 60 and is easily dissolved. For this reason, θ is preferably small for the removal of the sacrificing layer. Specifically, θ is preferably 150 degrees or less and more preferably 120 degrees or less.

The red light-emitting layer 44r may be formed such that, for example, the angle θ between the outer side face and the lower face 66r of the red light-emitting layer 44r is more than 0 degrees and equal to or less than 90 degrees. At this time, the smaller the angle θ is, the larger the area of the upper face of the first photoresist layer 43r is. Thus, the first photoresist layer 43r is open to the stripper 60 and is easily dissolved. For this reason, θ is preferably small for the removal of the sacrificing layer. Specifically, θ is preferably 60 degrees or less and more preferably 30 degrees or less.

In the configuration according to the comparative example, since the length of the edge of the recess 250r is small, it is difficult for the stripper 60 to reach the photoresist layer 243r, and the permeation of the stripper 60 into the photoresist layer 243r may be insufficient in some cases. For this reason, the configuration of the comparative example has a problem that patterning failure of the red light-emitting layer 244r is likely to occur. On the other hand, as described above, since the length of the edge 56r of the first recess 50r according to the disclosure is large, the stripper 60 easily reaches the first photoresist layer 43r, and the stripper 60 easily sufficiently permeates into the first photoresist layer 43r. Thus, the method according to the disclosure can advantageously reduce patterning failure of the red light-emitting layer 44r.

In addition, even when the red light-emitting layer 44r is made thick, the stripper 60 is likely to sufficiently permeate into the first photoresist layer 43r. Thus, in the method according to the disclosure, the red light-emitting layer 44r can be advantageously patterned even when the red light-emitting layer 44r is thick. That is, the red light-emitting layer 44r can be made thick.

According to the method of the disclosure, since an outer shape of the red light-emitting layer 44r has protrusions and recesses, a stress applied to the red light-emitting layer 44r and a stress generated at the red light-emitting layer 44r are dispersed. Bending resistance and thermal stress resistance of the red light-emitting layer 44r can be improved due to the stress dispersion.

In the method according to the disclosure, the red light-emitting material layer 144r preferably contains a quantum dot so that the stripper 60 permeates the red light-emitting material layer 144r and easily reaches the first photoresist layer 43r. Thus, the red light-emitting layer 44r includes a quantum dot as a light-emitting material. A particle diameter of the quantum dot is 1 nm or more and 100 nm or less.

### Process of Forming Green Light-Emitting Layer

Subsequently, a process of forming the green light-emitting layer 44g (step S28g) is performed. Step S28g may be similar to step S28r. Hereinafter, for simplification of description, an example in which a second photoresist layer 43g contains a positive resist will be described.

As illustrated in FIG. 7, first, similarly to the first photoresist layer 43r, the second photoresist layer 43g (a second sacrificing layer) is formed in the entire display region (step S50). Next, the second photoresist layer 43g is patterned by using a photolithography technique (step S52).

As illustrated in FIG. 16, as a result of the patterning, a second recess 50g is formed in the second photoresist layer 43g. The second recess 50g is formed at a position where the green light-emitting layer 44g is to be formed in the future. The second recess 50g according to the present embodiment extends through the second photoresist layer 43g, and the hole transport layer 42 is exposed from the second recess 50g. In a plan view, a shape of the second recess 50g is equivalent to a shape of the green light-emitting layer 44g to be formed in the future, and thus, a contour of the second recess 50g includes a recessed figure (second recessed figure).

To prevent electric field concentration or short-circuiting in the green light-emitting layer 44g, the second recess 50g is preferably larger than the corresponding opening 23a of the edge cover 23 in a plan view from above. To stabilize etching of the second photoresist layer 43g in the patterning, the shape of the second recess 50g is preferably a shape having high regularity and/or high symmetry.

In addition, a length of an edge 56g of the second recess 50g according to the disclosure is larger than the length of the edge of the recess for forming the green light-emitting layer 244g according to the comparative example.

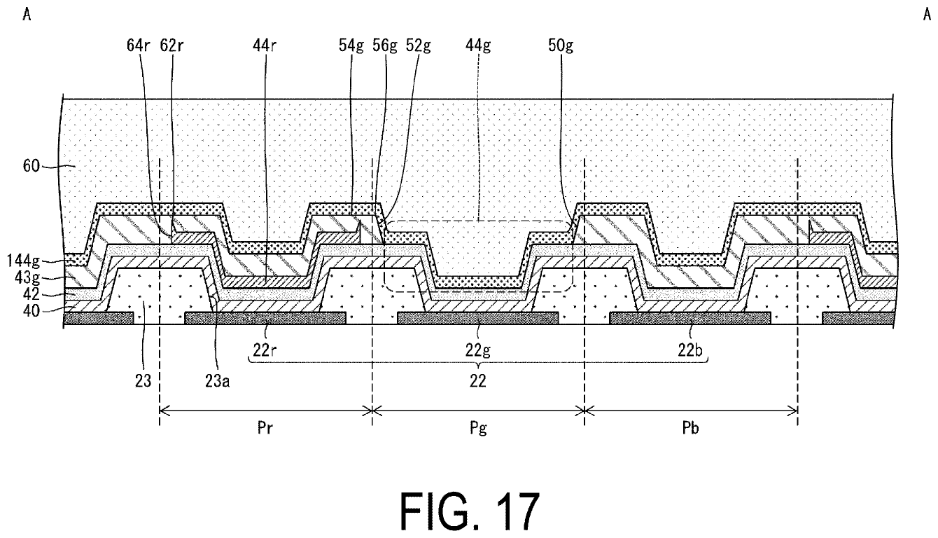

As illustrated in FIG. 17, next, a green light-emitting material layer 144g (second functional material layer) is formed at least in the second recess 50g (step S54). Similarly to the formation method of the red light-emitting material layer 144r, the green light-emitting material layer 144g may be formed by any method such as coating, vapor deposition, or sputtering. Normally, the green light-emitting material layer 144g is formed over the entire display region. Similarly to the above description, the shape of the second recess 50g is preferably a shape having high regularity and/or high symmetry so that a liquid containing a light-emitting material uniformly spreads in the second recess 50g.

Next, all the second photoresist layer 43g is removed using the stripper 60 (step S56). The green light-emitting material layer 144g is thin at the edge 56g of the second recess 50g and in the vicinity thereof (hereinafter referred to as “in the vicinity of the edge 56g”). In some cases, the green light-emitting material layer 144g may be discontinuous in the vicinity of the edge 56g. For this reason, the stripper 60 easily reaches the second photoresist layer 43g in the vicinity of the edge 56g.

The edge 56g of the second recess 50g is an edge between the side face 52g and the upper face 54g of the second photoresist layer 43g. When the edge 56g has an angular corner, the green light-emitting material layer 144g tends to be thin in the vicinity of the edge 56g and tends to be easily disconnected as compared with a case where the edge 56g has a rounded corner. For this reason, the edge 56g of the second recess 50g preferably has an angular corner.

When the stripper 60 is removed in step S56, the second photoresist layer 43g dissolved in the stripper 60 is also removed together. Furthermore, a portion of the green light-emitting material layer 144g formed on the second photoresist layer 43g is also peeled off and removed together. As a result, the green light-emitting material layer 144g is patterned, and a portion of the green light-emitting material layer 144g formed in the second recess 50g remains as the green light-emitting layer 44g.

An end portion of the green light-emitting layer 44g usually includes a burr portion similarly to the end portion of the red light-emitting layer 44r. The burr portion is derived from a portion of the green light-emitting material layer 144g that has crept up a side face 52g of the second photoresist layer 43g. In addition, at least part of an outer side face of the green light-emitting layer 44g is a face that has been in contact with the side face 52g of the second photoresist layer 43g. The face that has been in contact with the second photoresist layer 43g is separated from the edge cover 23. Thus, at least part of the outer side face of the green light-emitting layer 44g is separated from the edge cover 23.

According to the method of the disclosure, since a length of the edge 56g of the second recess 50g is large, the stripper 60 can sufficiently permeate into the second photoresist layer 43g. Thus, the method according to the disclosure can advantageously reduce patterning failure of the green light-emitting layer 44g. Also, when the method according to the disclosure is used, the green light-emitting layer 44g can be advantageously made thicker.

According to the method of the disclosure, since an outer shape of the green light-emitting layer 44g has protrusions and recesses, a stress applied to the green light-emitting layer 44g and a stress generated at the green light-emitting layer 44g are dispersed. Bending resistance and thermal stress resistance of the green light-emitting layer 44g can be improved due to the stress dispersion.

In the method according to the disclosure, the green light-emitting material layer 144g preferably contains a quantum dot so that the stripper 60 can permeate the green light-emitting material layer 144g and easily reach the second photoresist layer 43g. Thus, the green light-emitting layer 44g preferably contains a quantum dot as a light-emitting material.

### Process of Forming Blue Light-Emitting Layer

Subsequently, a process of forming the blue light-emitting layer 44b (step S28b) is performed. Step S28b may be similar to step S28r. Hereinafter, for simplification of description, an example in which a third photoresist layer 43b contains a positive resist will be described.

As illustrated in FIG. 7, first, similarly to the first photoresist layer 43r, the third photoresist layer 43b (a second sacrificing layer) is formed in the entire display region (step S50). Next, the third photoresist layer 43b is patterned by using a photolithography technique (step S52).

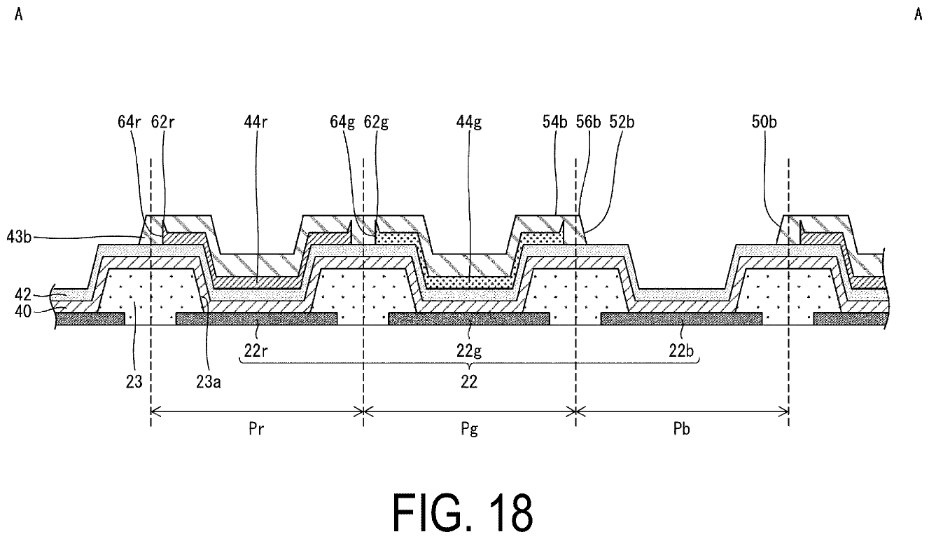

As illustrated in FIG. 18, as a result of the patterning, a third recess 50b is formed in the third photoresist layer 43b. The third recess 50b is formed at a position where the blue light-emitting layer 44b is to be formed in the future. The third recess 50b according to the present embodiment extends through the third photoresist layer 43b, and the hole transport layer 42 is exposed from the third recess 50b. In a plan view, a shape of the third recess 50b is equivalent to a shape of the blue light-emitting layer 44b to be formed in the future, and thus, a contour of the third recess 50b includes a recessed figure (third recessed figure).

To prevent electric field concentration or short-circuiting in the blue light-emitting layer 44b, a bottom face of the third recess 50b is preferably larger than the corresponding opening 23a of the edge cover 23 in a plan view from above. To stabilize etching of the third photoresist layer 43b in the patterning, the shape of the third recess 50b is preferably a shape having high regularity and/or high symmetry.

In addition, a length of an edge 56b of the third recess 50b according to the disclosure is larger than the length of the edge of the recess for forming the blue light-emitting layer 244b according to the comparative example.

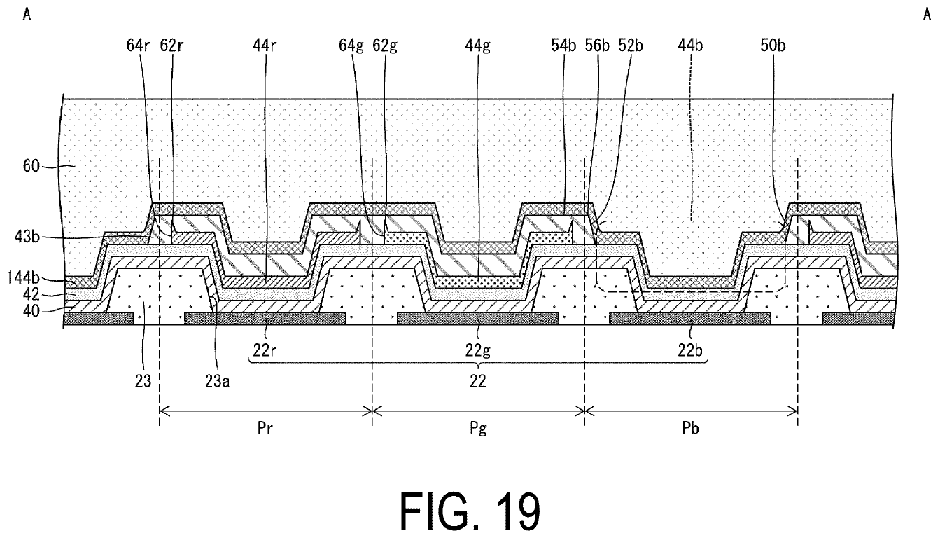

As illustrated in FIG. 19, next, a blue light-emitting material layer 144b is formed at least in the third recess 50b (step S54). Similarly to the formation method of the red light-emitting material layer 144r, the blue light-emitting material layer 144b may be formed by any method such as coating, vapor deposition, or sputtering. Normally, the blue light-emitting material layer 144b is formed over the entire display region.

Next, all the third photoresist layer 43b is removed by using the stripper 60 (step S56). The blue light-emitting material layer 144b is thin at the edge 56b of the third recess 50b and in the vicinity thereof (hereinafter referred to as “in the vicinity of the edge 56b”). In some cases, the blue light-emitting material layer 144b may be discontinuous in the vicinity of the edge 56b. Thus, the stripper 60 easily reaches the third photoresist layer 43b in the vicinity of the edge 56b.

The edge 56b of the third recess 50b is an edge between an upper face 54b and a side face 52b of the third photoresist layer 43b. When the edge 56b has an angular corner, the blue light-emitting material layer 144b tends to be thin in the vicinity of the edge 56b and tends to be easily disconnected as compared with a case where the edge 56b has a rounded corner. For this reason, the edge 56b of the third recess 50b preferably has an angular corner.

When the stripper 60 is removed in step S56, the third photoresist layer 43b dissolved in the stripper 60 is also removed together. Furthermore, a portion of the blue light-emitting material layer 144b formed on the third photoresist layer 43b is also removed together. As a result, the blue light-emitting material layer 144b is patterned, and a portion of the blue light-emitting material layer 144b formed in the third recess 50b remains as the blue light-emitting layer 44b.

An end portion of the blue light-emitting layer 44b usually includes a burr portion extending upward, similarly to the end portion of the red light-emitting layer 44r. The burr portion is derived from a portion of the blue light-emitting material layer 144b that has crept up the side face 52b of the third photoresist layer 43b. In addition, at least part of an outer side face of the blue light-emitting layer 44b is a face that has been in contact with the side face 52b of the third photoresist layer 43b. The face that has been in contact with the third photoresist layer 43b is separated from the edge cover 23. Thus, at least part of the outer side face of the blue light-emitting layer 44b is separated from the edge cover 23.

According to the method of the disclosure, since a length of the edge 56b of the third recess 50b is large, the stripper 60 can sufficiently permeate into the third photoresist layer 43b. Thus, the method according to the disclosure can advantageously reduce patterning failure of the blue light-emitting layer 44b. Also, in the method according to the disclosure, the blue light-emitting layer 44b can be advantageously made thicker.

According to the method of the disclosure, further, since an outer shape of the blue light-emitting layer 44b has protrusions and recesses, a stress applied to the blue light-emitting layer 44b and a stress generated at the blue light-emitting layer 44b are dispersed. Bending resistance and thermal stress resistance of the blue light-emitting layer 44b can be improved because of the stress dispersion.

In the method according to the disclosure, the blue light-emitting material layer 144b preferably contains a quantum dot so that the stripper 60 permeates the blue light-emitting material layer 144b and easily reaches the third photoresist layer 43b. Thus, the blue light-emitting layer 44b preferably contains a quantum dot as a light-emitting material.

### Shapes and Arrangements of Light-Emitting Layer and Recesses

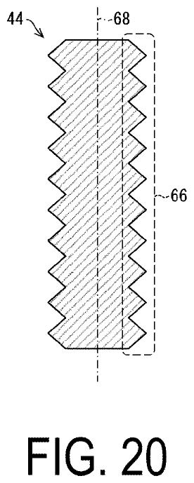

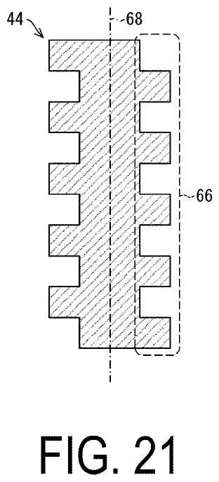

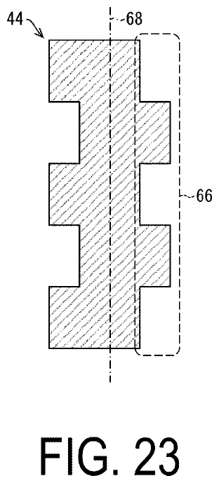

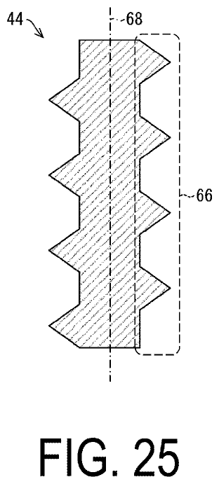

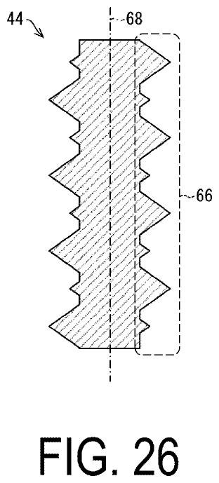

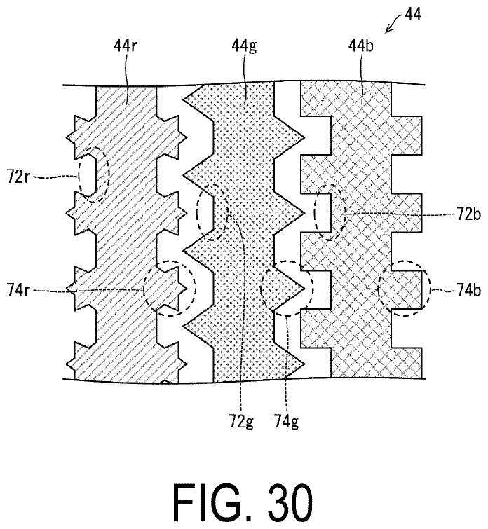

FIG. 20 to FIG. 29 are plan views illustrating various shape examples of the light-emitting layer 44 according to the disclosure. FIG. 30 to FIG. 35 are plan views illustrating various arrangement examples of the light-emitting layer 44 according to the disclosure. Note that a shape and an arrangement suitable for the light-emitting layer 44 are also a shape and an arrangement suitable for the first recess 50r, the second recess 50g, and the third recess 50b.

In this column, a “minimum protruding figure” means a protruding figure having a minimum area among protruding figures surrounding recessed figures included in the contour of the light-emitting layer 44. The protruding figure having the minimum area is a protruding figure that surrounds the recessed figure so as not to pass through the inside of the recessed figure and that has an outer periphery having a minimum length.

It is preferable that the lengths of the edges 56r, 56g, and 56b of the first recess 50r, the second recess 50g, and the third recess 50b are sufficiently large so that the stripper 60 can sufficiently reach the first photoresist layer 43r, the second photoresist layer 43g, and the third photoresist layer 43b. Thus, it is preferable that the peripheral length of the light-emitting layer 44 is sufficiently large. Specifically, it is preferable that A is larger than 1.1 times B, where A is a peripheral length of the recessed figure of the light-emitting layer 44 and B is a peripheral length of the protruding figure having the minimum area. Also, for example, A is 1.1 to 1.3 times, 1.3 to 1.5 times, 1.5 to 2 times, or more than 2 times B.

As illustrated in FIG. 20 to FIG. 29, the recessed figure included in the contour of the light-emitting layer 44 may have an elongated shape.

In a case where the contour of the light-emitting layer 44 is elongated, D is preferably larger than 1.1 times E, where D is a length of a contour portion 66 of the light-emitting layer 44 and E is a length of a line segment connecting both ends of the contour portion 66. Also, for example, D is 1.1 to 1.3 times, 1.3 to 1.5 times, 1.5 to 2 times, or more than 2 times E. Here, the contour portion 66 is part of the outer shape of the light-emitting layer 44. The contour portion 66 is part of the contour of the light-emitting layer 44 cut out such that a line segment connecting both ends of the contour portion 66 is substantially parallel to a long axis of the light-emitting layer 44 and the contour portion 66 does not cross a center line 68 parallel to the long axis of the light-emitting layer 44. Here, the center line 68 is a straight line that traverses the light-emitting layer 44 such that an area of a region of the light-emitting layer 44 positioned on one side of the center line 68 is equivalent to an area of a region of the light-emitting layer 44 positioned on the other side of the center line 68.

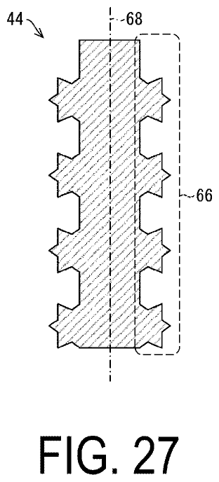

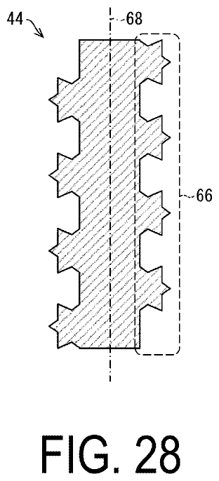

For example, as illustrated in FIG. 27 and FIG. 28, the contour portion 66 preferably includes a fractal structure. Here, the fractal structure refers to as a structure including part where part and the entirety of a figure are self-similar. For example, in FIG. 27, a triangular projection is formed in part of the contour of the light-emitting layer 44, and a triangular projection similar to the triangular projection is further formed on a side face of the triangular projection. Such a shape has an advantage that a length along the contour portion 66 is larger than a length of the line segment connecting both ends of the contour portion 66 due to the fractal structure.

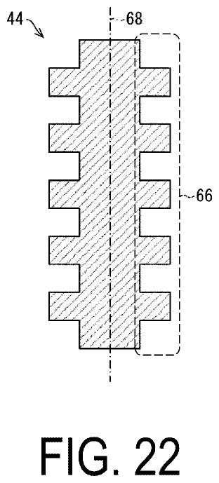

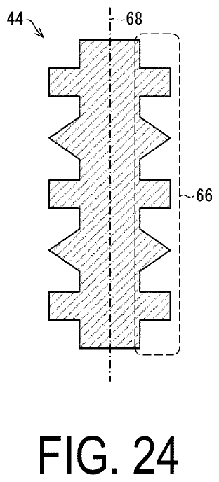

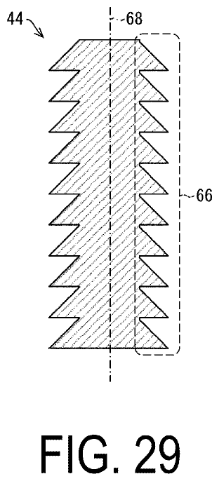

For example, as illustrated in FIG. 20, FIG. 22, FIG. 24 to FIG. 26, and FIG. 29, it is preferable that a width in a short axis direction of the recessed figure of the light-emitting layer 44 is regularly and repeatedly increased and decreased along the long axis of the recessed figure. In other words, the contour of the light-emitting layer 44 preferably has a zigzag shape or a meandering shape.

For example, as illustrated in FIG. 20 to FIG. 29, the recessed figure of the light-emitting layer 44 preferably has line symmetry or rotation symmetry. Since such shapes have high regularity and/or symmetry, as described above, there are advantages that etching conditions of the first photoresist layer 43r, the second photoresist layer 43g, and the third photoresist layer 43b are easily stabilized, and that a liquid containing a light-emitting material is easily and uniformly spread in the first recess 50r, the second recess 50g, and the third recess 50b.

For example, as illustrated in FIG. 30, the shapes of the red light-emitting layer 44r, the green light-emitting layer 44g, and the blue light-emitting layer 44b may be different from one another. Additionally, although not illustrated, the red light-emitting layers 44r may have different shapes from each other, the green light-emitting layers 44g may have different shapes from each other, and the blue light-emitting layers 44b may have different shapes from each other.

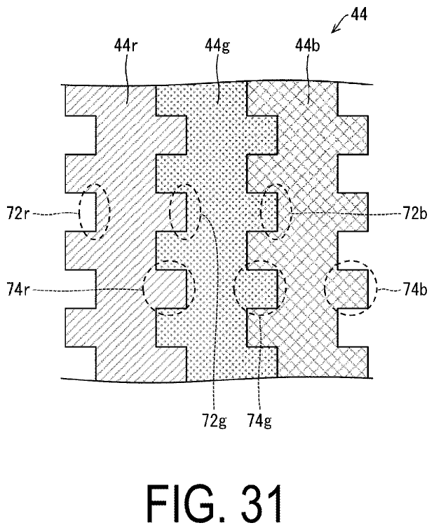

For example, as illustrated in FIG. 31, the red light-emitting layer 44r, the green light-emitting layer 44g, and the blue light-emitting layer 44b may mutually have the same shape.

As illustrated in FIG. 30 and FIG. 31, it is preferable that the light-emitting layers 44 be arranged so that the protrusions and recesses of the contours of the light-emitting layers 44 adjacent to each other engage with each other.

For example, when the red light-emitting layer 44r and the green light-emitting layer 44g are adjacent to each other in a plan view from above, it is preferable that a portion (hereinafter referred to as a “recessed portion”) 72r where the contour of the red light-emitting layer 44r is recessed face a portion (hereinafter referred to as a “protruding portion”) 74g where the contour of the green light-emitting layer 44g protrudes, and a portion (hereinafter referred to as a “protruding portion”) 74r where the contour of the red light-emitting layer 44r protrudes face a portion (hereinafter referred to as a “recessed portion”) 72g where the contour of the green light-emitting layer 44g is recessed.

In addition, for example, when the green light-emitting layer 44g and the blue light-emitting layer 44b are adjacent to each other in a plan view from above, it is preferable that the portion (hereinafter referred to as a “recessed portion”) 72g where the contour of the green light-emitting layer 44g is recessed face a portion (hereinafter referred to as a “protruding portion”) 74b where the contour of the blue light-emitting layer 44b protrudes, and the portion (hereinafter referred to as a “protruding portion”) 74g where the contour of the green light-emitting layer 44g protrudes face a portion (hereinafter referred to as a “recessed portion”) 72b where the contour of the blue light-emitting layer 44b is recessed.

In addition, for example, when the blue light-emitting layer 44b and the red light-emitting layer 44r are adjacent to each other in a plan view from above, it is preferable that the portion (hereinafter referred to as a “recessed portion”) 72b where the contour of the blue light-emitting layer 44b is recessed face the portion (hereinafter referred to as a “protruding portion”) 74r where the contour of the red light-emitting layer 44r protrudes, and the portion (hereinafter referred to as a “protruding portion”) 74b where the contour of the blue light-emitting layer 44b protrudes face the portion (hereinafter referred to as a “recessed portion”) 72r where the contour of the red light-emitting layer 44r is recessed.

In this case, since the protruding portion and the recessed portion of the contours of the light-emitting layers 44 adjacent to each other face each other, an area and a maximum width of each light-emitting layer 44 can be increased. Thus, adhesion between each light-emitting layer 44 and an underlying layer thereof is improved, and charge transport efficiency to each light-emitting layer is improved. To further increase the area and the maximum width of each light-emitting layer 44, as illustrated in FIG. 31, the red light-emitting layer 44r, the green light-emitting layer 44g, and the blue light-emitting layer 44b are preferably in contact with each other in a plan view from above.

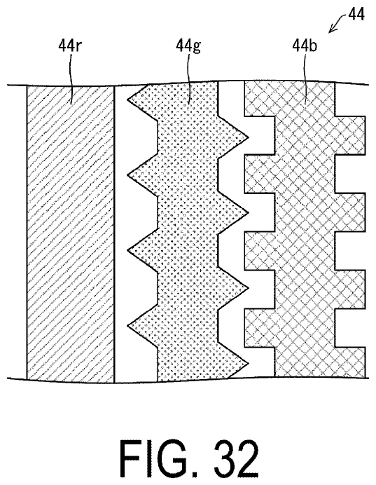

On the other hand, as illustrated in FIG. 30 and FIG. 32, it is also preferable that the red light-emitting layer 44r, the green light-emitting layer 44g, and the blue light-emitting layer 44b be separated from each other in a plan view from above. Since the light-emitting layers 44 are separated from each other, the light-emitting layers 44 having different colors can be prevented from overlapping each other due to manufacturing errors or the like.

As illustrated in FIG. 32, the light-emitting element layer 5 may include the red light-emitting layer 244r having a protruding figure, the green light-emitting layer 44g having a recessed figure, and the blue light-emitting layer 44b having a recessed figure. In addition to this, the light-emitting element layer 5 including one or more light-emitting layers 44 each of which has a recessed figure and a method for manufacturing the same are included in the scope of the disclosure.

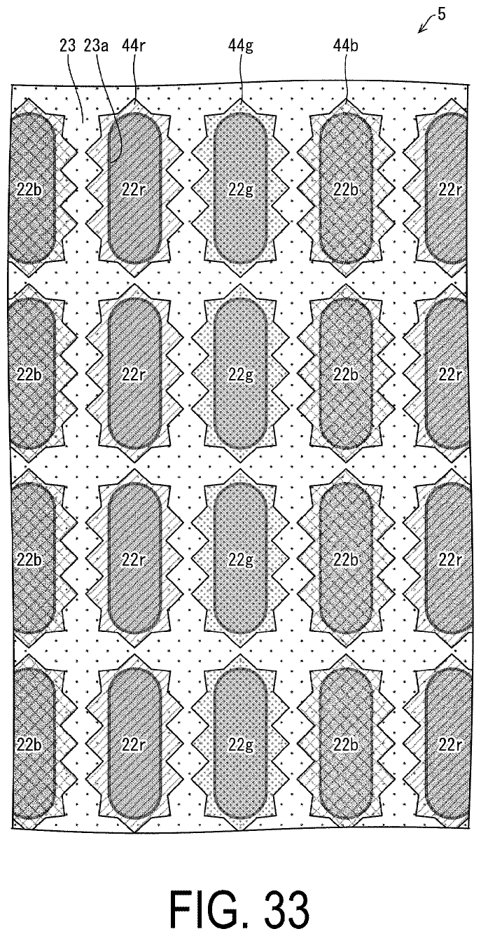

As illustrated in FIG. 33, the light-emitting layers 44 may be formed so as to correspond one to one to the openings 23a of the edge cover 23.

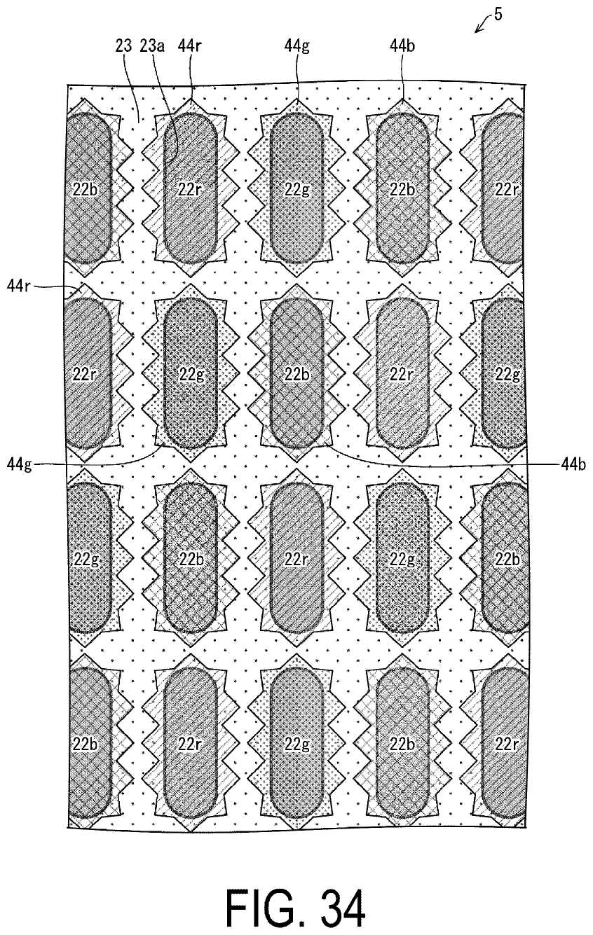

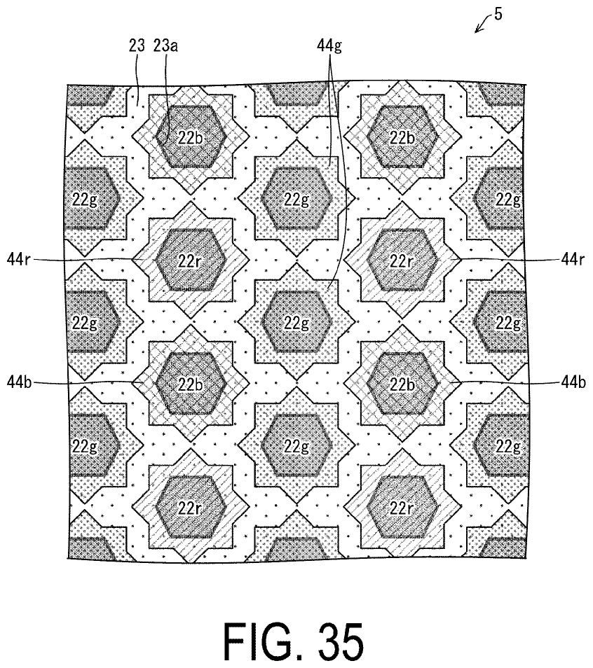

As illustrated in FIG. 4, FIG. 34, and FIG. 35, the light-emitting layers 44 may be arranged according to a freely selected array such as a stripe array, an oblique array, and a delta array.

### Second Embodiment

Another embodiment of the disclosure will be described below. Further, members having the same functions as those of the members described in the above-described embodiment will be denoted by the same reference numerals and signs, and the description thereof will not be repeated for the sake of convenience of description.

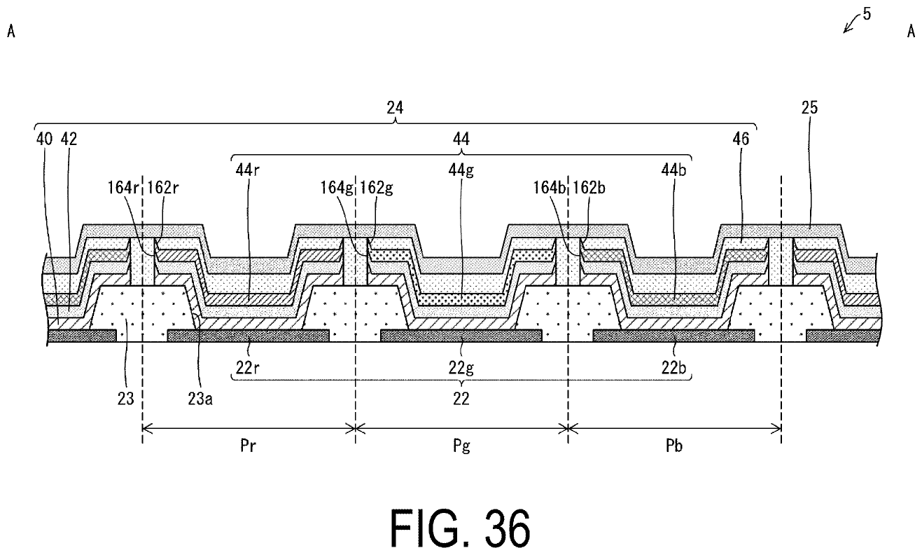

FIG. 36 is a schematic cross-sectional view illustrating an example of a configuration in the display region of the light-emitting element layer 5 according to an embodiment of the disclosure.

A method of forming the light-emitting element layer 5 according to the present embodiment is different from the method of forming the light-emitting element layer 5 according to the first embodiment described above in that the hole injection layer 40 and the hole transport layer 42 are patterned simultaneously together with the light-emitting layer 44. The method of forming the light-emitting element layer 5 according to the present embodiment is equivalent to the method of forming the light-emitting element layer 5 according to the first embodiment described above in other respects.

As illustrated in FIG. 36, as a result, the hole injection layer 40 according to the present embodiment is patterned so as to include a red hole injection layer 40r corresponding to the red light-emitting layer 44r, a green hole injection layer 40g corresponding to the green light-emitting layer 44g, and a blue hole injection layer 40b corresponding to the blue light-emitting layer 44b. Similarly, the hole transport layer 42 according to the present embodiment is patterned so as to include a red hole transport layer 42r corresponding to the red light-emitting layer 44r, a green hole transport layer 42g corresponding to the green light-emitting layer 44g, and a blue hole transport layer 42b corresponding to the blue light-emitting layer 44b.

According to the method of the first embodiment described above, the light-emitting layer 44 can be patterned even when the light-emitting layer 44 is thick. Thus, the hole injection layer 40, the hole transport layer 42, and the light-emitting layer 44 can be patterned together. Additionally, the method of forming the light-emitting element layer 5 according to the present embodiment can obtain an effect similar to that of the method of forming the light-emitting element layer 5 according to the first embodiment described above.

In addition to this, methods for simultaneously patterning a function layer including a plurality of layers and configurations obtained as results thereof are within the scope of the disclosure. In addition, the method according to the second embodiment may be combined with the method according to the first embodiment described above, and the combined method and a configuration obtained as a result thereof are also included in the scope of the disclosure.

### Third Embodiment

Another embodiment of the disclosure will be described below. Further, members having the same functions as those of the members described in the above-described embodiments will be denoted by the same reference numerals and signs, and the description thereof will not be repeated for the sake of convenience of description.

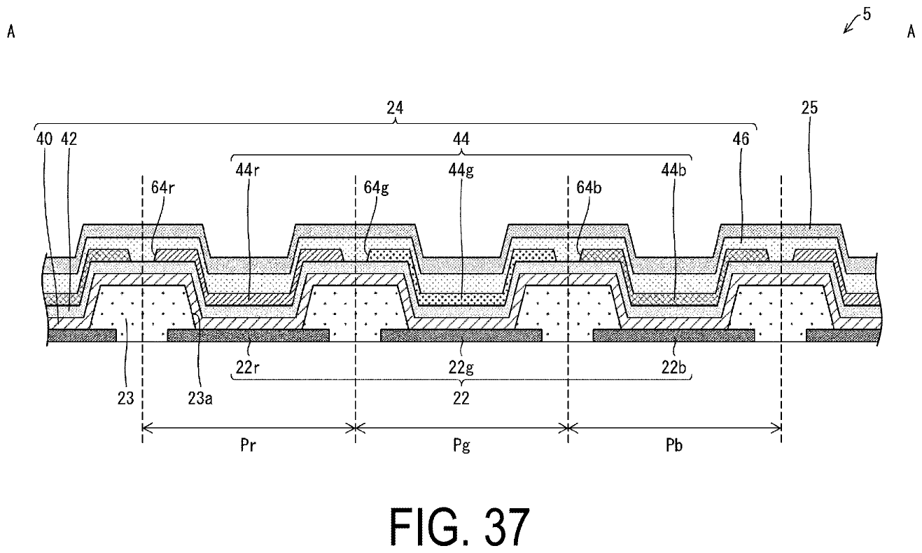

FIG. 37 is a schematic cross-sectional view illustrating an example of a configuration in the display region of the light-emitting element layer 5 according to an embodiment of the disclosure.

The method of forming the light-emitting element layer 5 according to the present embodiment is different from the method of forming the light-emitting element layer 5 according to the above-described first embodiment in that the light-emitting layer 44 is patterned by using a photoresist layer patterned in an inversely tapered shape in order not to form a burr portion in the light-emitting layer 44. The method of forming the light-emitting element layer 5 according to the present embodiment is equivalent to the method of forming the light-emitting element layer 5 according to the first embodiment described above in other respects.

### Process of Forming Light-Emitting Element Layer

Hereinafter, a process of forming the light-emitting element layer 5 according to the present embodiment (step S4) will be described.

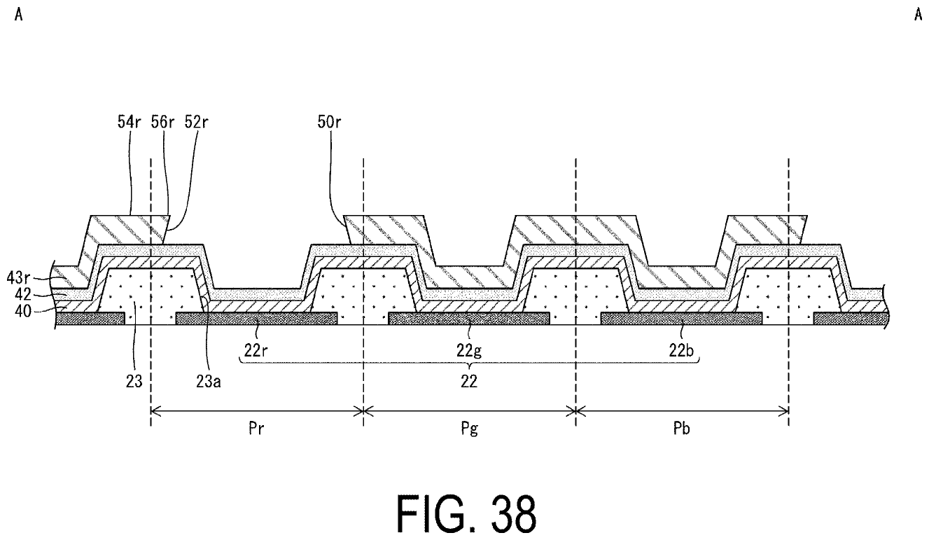

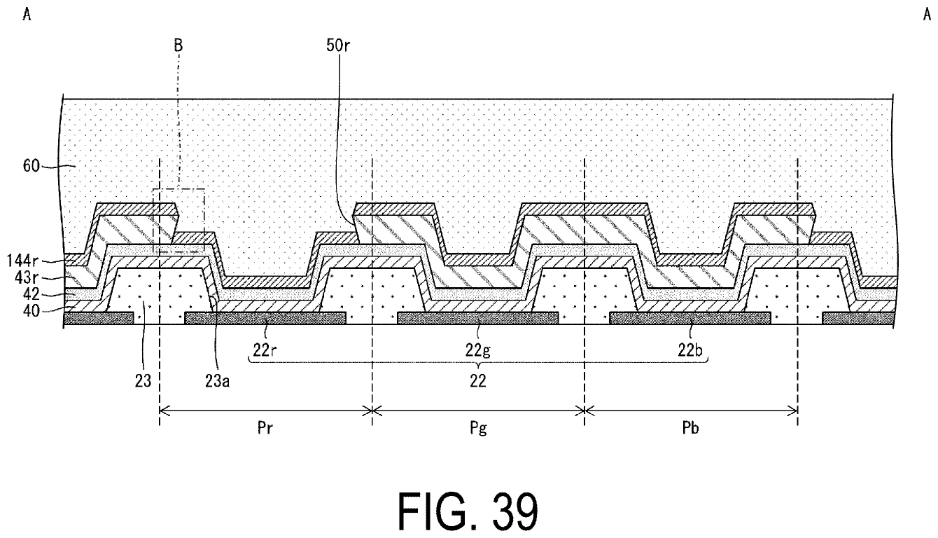

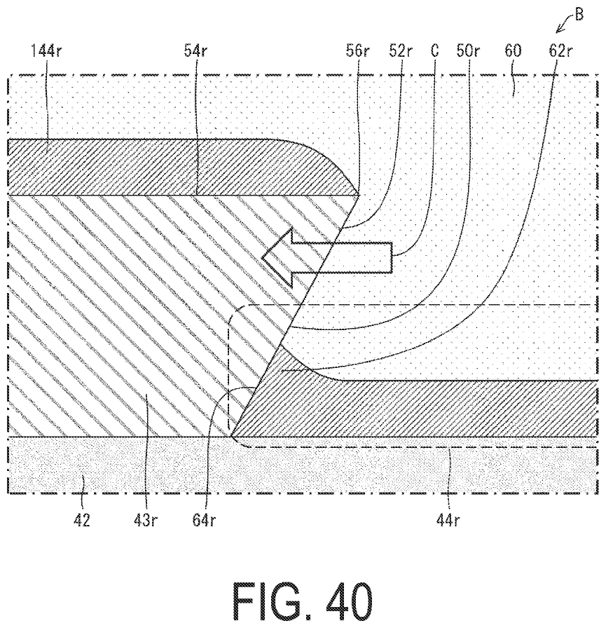

FIG. 38 and FIG. 39 are cross-sectional views illustrating the process of forming the light-emitting element layer 5 illustrated in FIG. 37. FIG. 40 is a partially enlarged cross-sectional view in which a portion surrounded by a box B in FIG. 39 is enlarged.

First, steps up to the forming of the first photoresist layer 43r (step S50) are performed in a manner similar to the first embodiment.

As illustrated in FIG. 38, next, the first photoresist layer 43r is patterned into an inversely tapered shape by using a photolithography technique (step S52). To be specific, the first recess 50r is formed such that the side face 52r of the first recess 50r faces obliquely downward. On the other hand, in the first embodiment described above, as illustrated in FIG. 9, the side face 52r of the first recess 50r faces obliquely upward, and the first photoresist layer 43r has a forwardly tapered shape.

Next, as illustrated in FIG. 39, the red light-emitting material layer 144r is formed at least in the first recess 50r (step S54). Next, all of the first photoresist layer 43r is removed using the stripper 60 (step S56).

As illustrated in FIG. 40, in step S54, since the first photoresist layer 43r has the inversely tapered shape, the red light-emitting material layer 144r hardly creeps up the side face 52r. Thus, according to the method of the present embodiment, the red light-emitting material layer 144r is thinner in the vicinity of the edge 56r of the first recess 50r and is more likely to be disconnected in the vicinity of the edge 56r as compared with the method in which the first photoresist layer 43r has the forwardly tapered shape. For this reason, as illustrated by an arrow C, it is easier for the stripper 60 to reach the first photoresist layer 43r in the vicinity of the edge 56r.

As a result, according to the method of the present embodiment, patterning failure of the red light-emitting layer 44r can be further reduced and the red light-emitting layer 44r can be further thickened.

As illustrated in FIG. 14, a portion of the red light-emitting material layer 144r formed in the first recess 50r remains as the red light-emitting layer 44r.

As illustrated in FIG. 40, an end portion of the red light-emitting layer 44r according to the present embodiment includes the burr portion 62r extending inward and upward. In addition, the face 64r of the red light-emitting layer 44r according to the present embodiment, the face 64r having been in contact with the first photoresist layer 43r, is separated from the edge cover 23, similarly to the face 64r according to the above-described first embodiment, and faces obliquely upward.

Also according to the method of the present embodiment, bending resistance and thermal stress resistance of the red light-emitting layer 44r can be improved as in the method according to the first embodiment described above.

Subsequently, forming of the green light-emitting layer 44g (step S28g) is similarly performed and forming of the blue light-emitting layer 44b (step S28b) is similarly performed. Next, the electron transport layer 46 is formed (step S30), and the common electrode 25 is formed (step S32). This forms the light-emitting element layer 5 illustrated in FIG. 3 and FIG. 4.

As described above, the method of forming the light-emitting element layer 5 according to the present embodiment can obtain an effect similar to that of the light-emitting element layer 5 according to the first embodiment described above. The method according to the third embodiment may be combined with the methods according to the first and second embodiments described above, and the combined method and a configuration obtained as a result thereof are also included in the scope of the disclosure.

### Fourth Embodiment

Another embodiment of the disclosure will be described below. Further, members having the same functions as those of the members described in the above-described embodiments will be denoted by the same reference numerals and signs, and the description thereof will not be repeated for the sake of convenience of description.

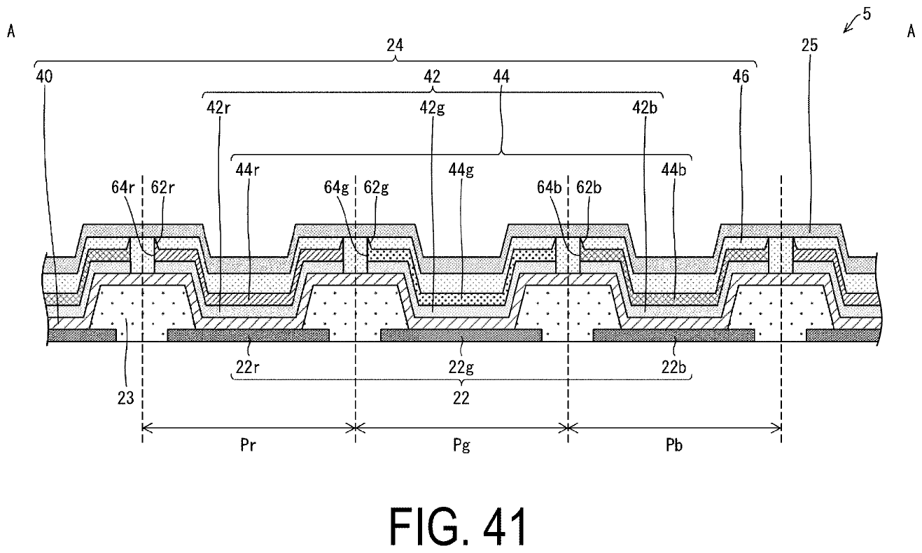

FIG. 41 is a schematic cross-sectional view illustrating an example of a configuration in the display region of the light-emitting element layer 5 according to the present embodiment.

The method of forming the light-emitting element layer 5 according to the present embodiment is different from the method of forming the light-emitting element layer 5 according to the first embodiment described above in that a portion of the photoresist layer for patterning the light-emitting layer 44 remains as the hole transport layer 42. The method of forming the light-emitting element layer 5 according to the present embodiment is equivalent to the method of forming the light-emitting element layer 5 according to the first embodiment described above in other respects.

As illustrated in FIG. 41, as a result, the hole transport layer 42 according to the present embodiment is patterned so as to include the red hole transport layer 42r corresponding to the red light-emitting layer 44r, the green hole transport layer 42g corresponding to the green light-emitting layer 44g, and the blue hole transport layer 42b corresponding to the blue light-emitting layer 44b.

### Process of Forming Light-Emitting Element Layer

Hereinafter, a process of forming the light-emitting element layer 5 according to the present embodiment (step S4) will be described.

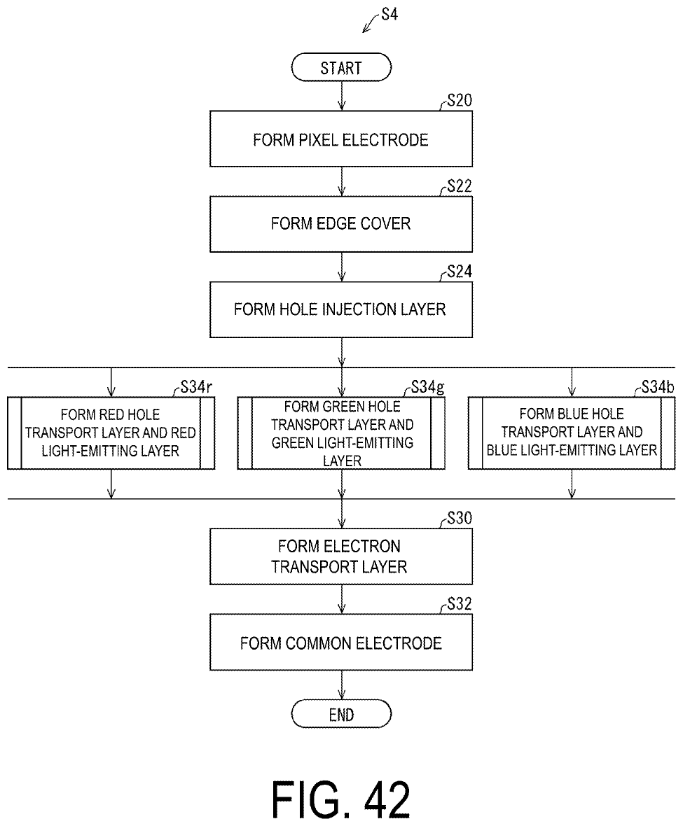

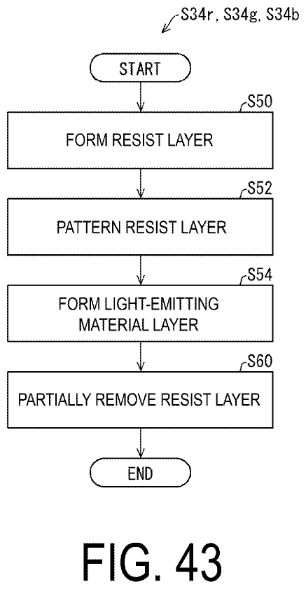

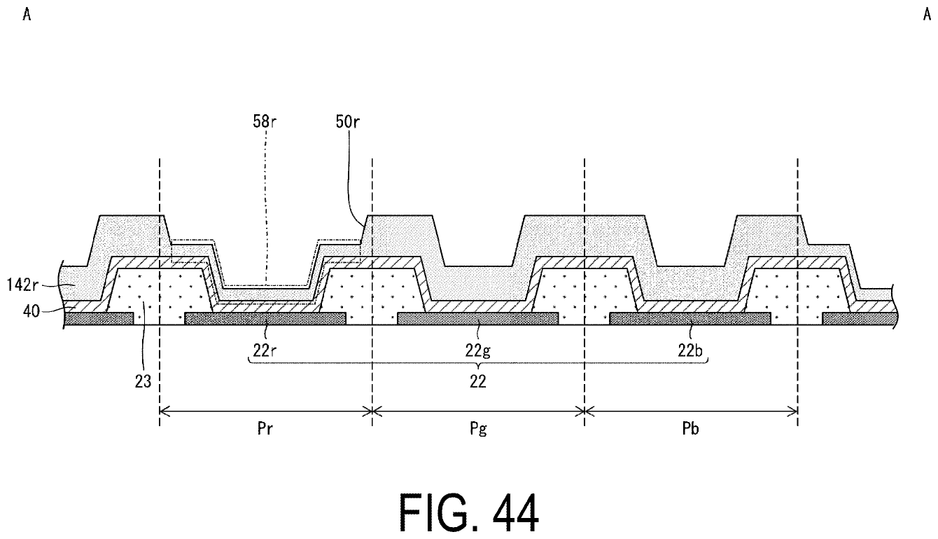

FIG. 42 is a flowchart illustrating an example of the process of forming the light-emitting element layer 5 (step S4) illustrated in FIG. 41. FIG. 43 is a flowchart illustrating an example of a process (steps S34r, S34g, and S34b) of forming the hole transport layer 42 and the light-emitting layer 44 illustrated in FIG. 41. FIG. 44 to FIG. 46 are cross-sectional views illustrating the process of forming the light-emitting element layer 5 according to the present embodiment.

First, steps up to the forming of the hole injection layer 40 (step S24) are performed in a manner similar to the first embodiment described above. Subsequently, forming of the red hole transport layer 42r and the red light-emitting layer 44r (step S34r), forming of the green hole transport layer 42g and the green light-emitting layer 44g (step S34g), and forming of the blue hole transport layer 42b and the blue light-emitting layer 44b (step S34b) are performed in a freely selected order by using a lift-off method. Hereinafter, for simplification of description, an example in which the hole transport layer 42 and the light-emitting layer 44 are formed in the order of red, green, and blue will be described.

The process of forming the red hole transport layer 42r and the red light-emitting layer 44r (step S28r) illustrated in FIG. 41 will be described below.

As illustrated in FIG. 43 and FIG. 44, first, a first photoresist layer 142r (first sacrificing layer) is formed over the entire display region (step S50). In step S50, a liquid containing a hole transport material in addition to a photoresist and a solvent is applied onto the hole injection layer 40 and prebaking is performed. Alternatively, a liquid containing a photoresist having a hole transport property and a solvent is applied onto the hole injection layer 40 and prebaking is performed. The photoresist may be positive-working or negative-working. The photoresist may be any of acrylic-based, novolac-based, rubber-based, styrene-based, and epoxy-based photoresists. Hereinafter, for simplification of description, an example in which the first photoresist layer 142r includes a positive-working photoresist (hereinafter referred to as a “positive resist”) will be described.

Then, the first photoresist layer 142r is patterned by using a photolithography technique.

As illustrated in FIG. 44, as a result of the patterning, the first recess 50r is formed in the first photoresist layer 142r. The first recess 50r according to the present embodiment is different from the first recess 50r according to the first embodiment described above in that the first recess 50r does not extend through the first photoresist layer 142r. That is, a remaining portion 58r of the first photoresist layer 142r remains below the bottom face of the first recess 50r. Such patterning can be performed by adjusting any one or more of exposure conditions, development conditions, sacrificing layer conditions, and the like. The exposure conditions include, for example, use of a halftone mask or a graytone mask, adjustment of an exposure amount, and adjustment of a depth of focus of exposure. The development conditions include, for example, a concentration of a developing solution, components of the developing solution, and a time length for which the first photoresist layer 142r is exposed to the developing solution. Conditions of the sacrificing layer include, for example, a thickness of the first photoresist layer 142r and a material of the first photoresist layers 142r.

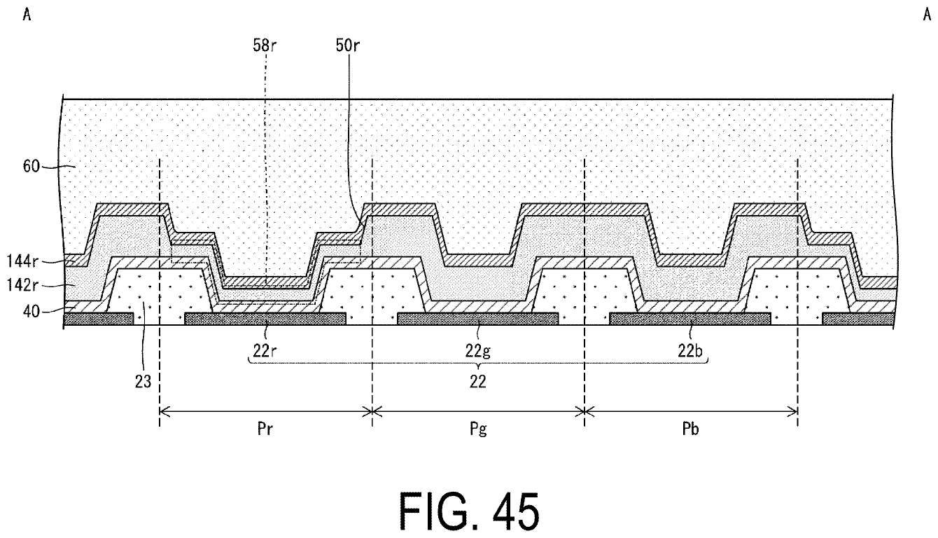

Next, as illustrated in FIG. 45, the red light-emitting material layer 144r is formed at least in the first recess 50r (step S54). Next, the first photoresist layer 142r is partially removed using the stripper 60 (step S60). In step S60, the remaining portion 58r of the first photoresist layer 142r is left and the other portion of the first photoresist layer 142r is removed. Such partial removal can be achieved by, for example, not exposing the remaining portion 58r to light but exposing the other portion to light, and then applying a developing solution as the stripper 60 onto the red light-emitting material layer 144r. When the first photoresist layer 142r includes a positive resist, the developing solution does not dissolve the remaining portion 58r not exposed to light, but dissolves the other portion exposed to light.

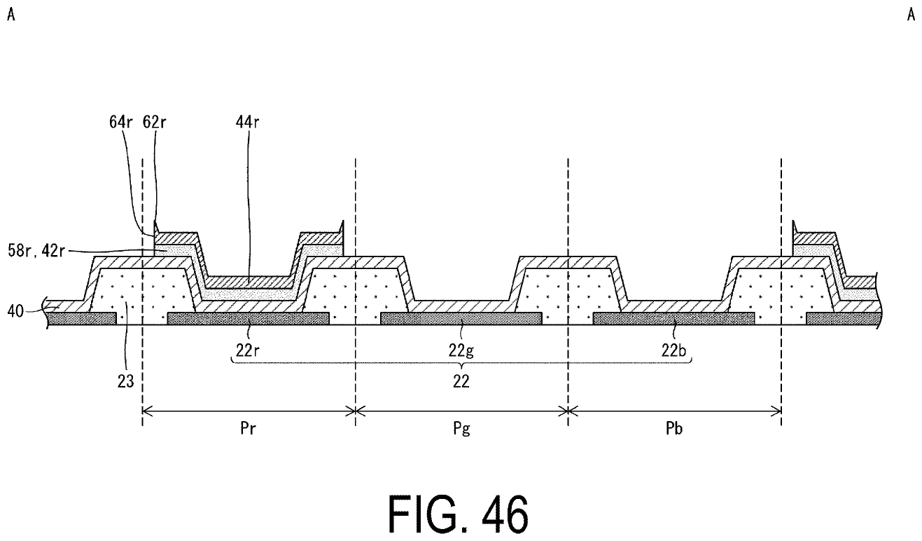

As illustrated in FIG. 46, when the stripper 60 is removed in step S56, the other portion of the first photoresist layer 142r dissolved in the stripper 60 is also removed together. As a result, the first photoresist layer 142r is patterned, and the remaining portion 58r of the first photoresist layer 142r remains as the red hole transport layer 42r. Furthermore, a portion of the red light-emitting material layer 144r formed on the other portion of the first photoresist layer 142r is also removed together. As a result, the red light-emitting material layer 144r is patterned, and a portion of the red light-emitting material layer 144r formed in the first recess 50r remains as the red light-emitting layer 44r.

Subsequently, the green hole transport layer 42g and the green light-emitting layer 44g are formed in a similar manner (step S34g), and the blue hole transport layer 42b and the blue light-emitting layer 44b are formed in a similar manner (step S34b). Step S34g and step S34b may be similar to step S34r.

Next, the electron transport layer 46 is formed (step S30), and the common electrode 25 is formed (step S32). This forms the light-emitting element layer 5 illustrated in FIG. 41.

According to the method of the fourth embodiment, the red hole transport layer 42r is formed from the first photoresist layer 142r for patterning the red light-emitting layer 44r. Similarly, the green hole transport layer 42g is formed from a second photoresist layer for patterning the green light-emitting layer 44g, and the blue hole transport layer 42b is formed from a third photoresist layer for patterning the blue light-emitting layer 44b. Thus, the manufacturing process of the light-emitting element layer 5 can be shortened.

In addition to this, any layer such as a charge injection layer, a charge transport layer, or a charge shielding layer may be formed from a photoresist layer or a template layer for patterning a function layer. For example, providing a charge shielding layer under the light-emitting layer 44 allows carrier balance in the light-emitting layer 44 to be improved, which improves characteristics of the display device 2. For example, when the photoresist layer contains a charge transport material, the carrier balance in the light-emitting layer 44 can be adjusted. In this case, the charge transport material is preferably a nanoparticle from the viewpoint of uniformity of the photoresist layer. For example, a template layer containing a charge transport material is formed, a photoresist layer is formed and patterned on the template layer, and the template layer is etched and patterned by using the photoresist layer as a protective mask. Then, a light-emitting material layer is formed on the template layer, and the template layer and the light-emitting material layer are lifted off. This allows the patterned charge transport layer 42 to be provided under the light-emitting layer 44.

Moreover, the process of forming the light-emitting element layer 5 according to the present embodiment can obtain an effect similar to that of the process of forming the light-emitting element layer 5 according to the first embodiment described above. It should be noted that the method according to the fourth embodiment may be combined with the methods according to the first, second, and third embodiments, and the combined method and a configuration obtained as a result thereof are also included in the scope of the disclosure.

### Fifth Embodiment

Another embodiment of the disclosure will be described below. Further, members having the same functions as those of the members described in the above-described embodiments will be denoted by the same reference numerals and signs, and the description thereof will not be repeated for the sake of convenience of description.

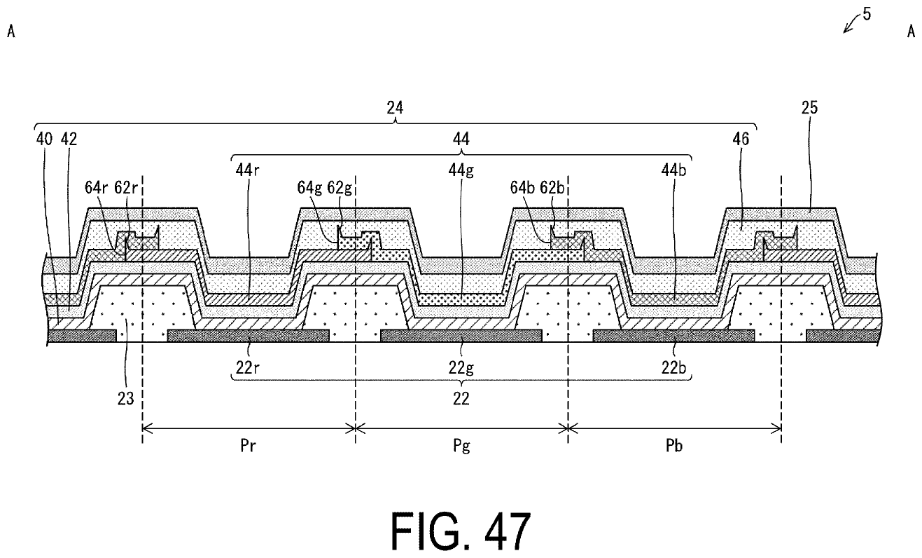

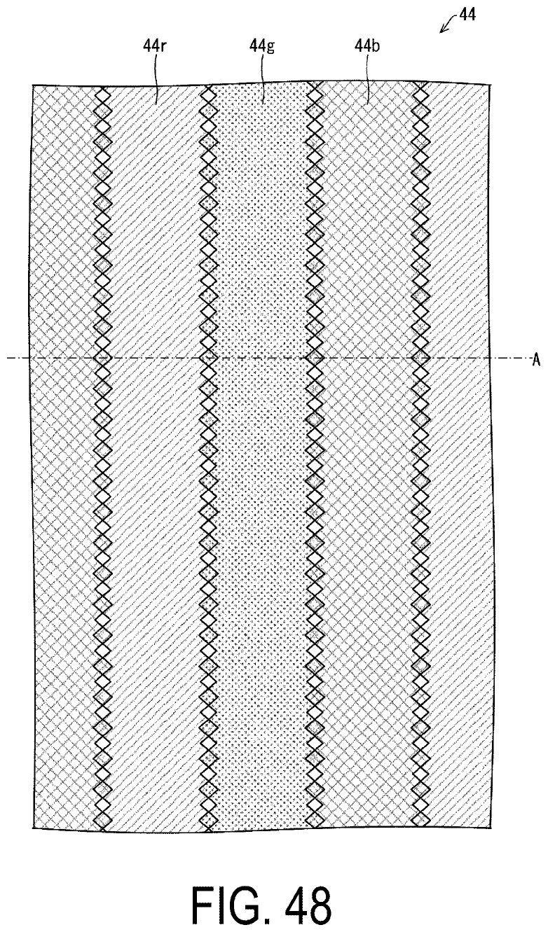

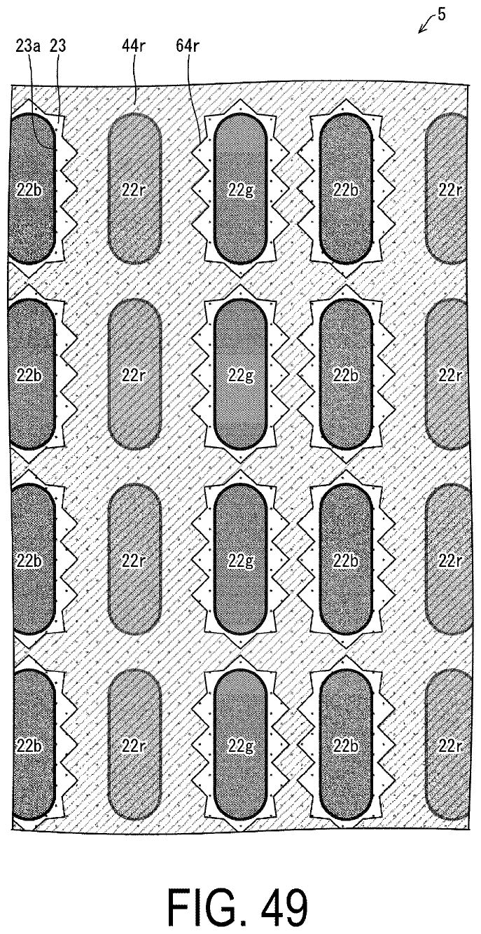

FIG. 47 is a schematic cross-sectional view illustrating an example of a configuration in the display region of the light-emitting element layer 5 according to a fifth embodiment. FIG. 48 is a schematic plan view illustrating a shape and an arrangement of the light-emitting layer 44 illustrated in FIG. 47. FIG. 49 is a schematic plan view illustrating a modified example of a shape of the red light-emitting layer 44r according to the fifth embodiment. FIG. 47 corresponds to a cross-sectional view taken along AA in FIG. 48.

The method of forming the light-emitting element layer 5 according to the present embodiment is different from the method of forming the light-emitting element layer 5 according to the first embodiment described above in that the light-emitting layers 44 are patterned such that the light-emitting layers 44 having different colors overlap each other. The method of forming the light-emitting element layer 5 according to the fifth embodiment is equivalent to the method of forming the light-emitting element layer 5 according to the first embodiment described above in other respects.

As illustrated in FIG. 47 and FIG. 48, as a result, in a plan view from above, part of the red light-emitting layer 44r and part of the green light-emitting layer 44g overlap each other, part of the red light-emitting layer 44r and part of the blue light-emitting layer 44b overlap each other, and part of the green light-emitting layer 44g and part of the blue light-emitting layer 44b overlap each other.

Such overlapping of the light-emitting layers 44 may cause problems such as dissolution and mixture of the light-emitting layers 44. To prevent this problem, it is preferable that the light-emitting layer 44 according to the present embodiment be subjected to insolubilization treatment and/or a material having low compatibility be used.

As an example of the insolubilization treatment, a thermosetting material is mixed with the material of the red light-emitting layer 44r, the red light-emitting layer 44r is patterned, and then the red light-emitting layer 44r is heated. According to this method, since the red light-emitting layer 44r is cured, even when the green light-emitting layer 44g or the blue light-emitting layer 44b is overlapped on the red light-emitting layer 44r, the red light-emitting layer 44r is not dissolved.

As an example of the insolubilization treatment, a dissolution preventing layer is formed so as to cover the red light-emitting layer 44r. The dissolution preventing layer is, for example, a resin layer containing a PVA-based compound, a PVP-based compound, an acrylic compound, a novolac-based compound, an imide-based compound or a silane-based compound. When it is desired to crosslink and polymerize the compound to improve a dissolution preventing effect, the dissolution preventing layer may appropriately contain a crosslinking agent (radical polymerization initiator). The crosslinking agent remains in the finished product. Examples of a photo-crosslinking agent include benzophenone-based, acetophenone-based, benzoin ether-based, thioxanthone-based, sulfonium salt-based, iodonium salt-based, primary to tertiary amine-based, amidine-based, and guanidine-based photo-crosslinking agents.

According to this method, since the red light-emitting layer 44r is covered with the dissolution preventing layer, even when the green light-emitting layer 44g or the blue light-emitting layer 44b is overlapped on the red light-emitting layer 44r, the red light-emitting layer 44r is not dissolved. In addition, as an effect obtained by the dissolution preventing layer remaining in the finished product, in a case where the dissolution preventing layer is a resin layer containing a hydrophobic compound, moisture entering the light-emitting element layer 5 is prevented from further advancing inside the element, which suppresses deterioration of the element.

As an example of the material having low compatibility, a quantum dot dispersed in a non-polar solvent such as octane is used as the material of the red light-emitting layer 44r, and a quantum dot dispersed in a polar solvent such as PGMEA is used as the material of the green light-emitting layer 44g. A non-polar solvent and a polar solvent are usually not mixed with each other. Thus, the material of the red light-emitting layer 44r is difficult to dissolve in the material of the green light-emitting layer 44g. For this reason, even when the green light-emitting layer 44g is overlapped on the red light-emitting layer 44r, the red light-emitting layer 44r is not dissolved.

### Modified Example of Shapes of Light-Emitting Layer and Recesses

As illustrated in FIG. 49, the red light-emitting layer 44r may be formed so as to cover the entire display region except for the openings 23a of the edge cover 23 corresponding to the green subpixel electrodes 22g and the vicinity of the openings 23a and the openings 23a of the edge cover 23 corresponding to the blue subpixel electrodes 22b and the vicinity of the openings 23a. Here, a shape of a non-formation region of the red light-emitting layer 44r is a recessed figure (first recessed figure).

Although not illustrated, the green light-emitting layer 44g may also be formed so as to cover the entire display region except for the openings 23a of the edge cover 23 corresponding to the red subpixel electrodes 22r and the vicinity of the openings 23a and the openings 23a of the edge cover 23 corresponding to the blue subpixel electrodes 22b and the vicinity of the openings 23a. Here, a shape of a non-formation region of the green light-emitting layer 44g is a recessed figure (second recessed figure).

Although not illustrated, the blue light-emitting layer 44b may also be formed so as to cover the entire display region except for the openings 23a of the edge cover 23 corresponding to the red subpixel electrodes 22r and the vicinity of the openings 23a and the openings 23a of the edge cover 23 corresponding to the green subpixel electrodes 22g and the vicinity of the openings 23. Here, a shape of a non-formation region of the blue light-emitting layer 44b is a recessed figure (third recessed figure).

The method of forming the light-emitting element layer 5 according to the present embodiment can obtain an effect similar to that of the method of forming the light-emitting element layer 5 according to the first embodiment described above. In addition, the method according to the fifth embodiment may be combined with the methods according to the first to fourth embodiments described above, and the combined method and a configuration obtained as a result thereof are also included in the scope of the disclosure.

### Sixth Embodiment

Another embodiment of the disclosure will be described below. Further, members having the same functions as those of the members described in the above-described embodiments will be denoted by the same reference numerals and signs, and the description thereof will not be repeated for the sake of convenience of description.

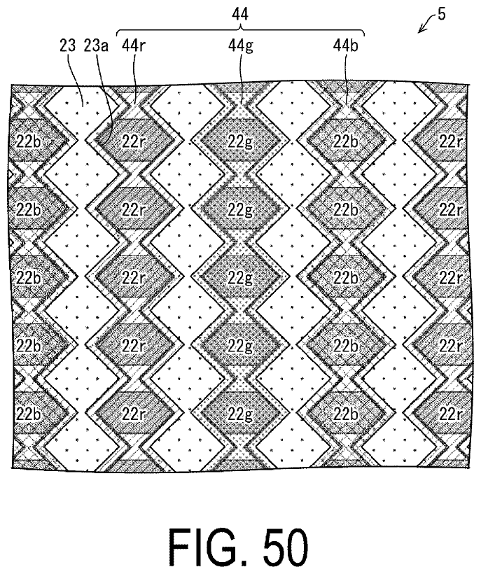

FIG. 50 is a schematic cross-sectional view illustrating an example of a configuration in the display region of the light-emitting element layer 5 according to a sixth embodiment.

The method of forming the light-emitting element layer 5 according to the present embodiment is different from the method of forming the light-emitting element layer 5 according to the first embodiment described above in that the shape of the opening 23a of the edge cover 23 is a recessed figure. The method of forming the light-emitting element layer 5 according to the sixth embodiment is equivalent to the method of forming the light-emitting element layer 5 according to the first embodiment described above in other respects.

As illustrated in FIG. 50, even when the shape of the opening 23a of the edge cover 23 is a recessed figure, the light-emitting layer 44 is usually larger than the corresponding opening 23a to prevent electric field concentration and short-circuiting. Thus, as in the first embodiment described above, at least part of the outer side face of the light-emitting layer 44 is separated from the edge cover 23.

Even when it is assumed that the size and shape of the light-emitting layer 44 are substantially the same as the size and shape of the corresponding opening 23a, since the light-emitting layer 44 according to the present embodiment is patterned by a lift-off method, the light-emitting layer 44 is deviated from the corresponding opening 23a due to manufacturing errors. Thus, at least part of the outer side face of the light-emitting layer 44 is separated from the edge cover 23.

The method of forming the light-emitting element layer 5 according to the present embodiment can obtain an effect similar to that of the method of forming the light-emitting element layer 5 according to the first embodiment described above. In addition, the method according to the sixth embodiment may be combined with the methods according to the first to fifth embodiments described above, and the combined method and a configuration obtained as a result thereof are also included in the scope of the disclosure.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

For example, in the above-described embodiments, the case where the function layer is the light-emitting layer has been mainly described, but the function layer may be a charge transport layer, a charge injection layer, or the like. In addition, the lower layer of the contour of the function layer differs depending on what the function layer is. In any case of the function layer, the function layer preferably contain a quantum dot or a nanoparticle so that the stripper can permeate the function layer and easily reach the photoresist layer or the template layer. The quantum dot or the nanoparticle is a particle having a particle diameter 1 nm or more and 100 nm or less.

1. A method for manufacturing a display device, the method comprising:
forming a first sacrificing layer;
forming a first recess in the first sacrificing layer;
forming a first functional material layer at least in the first recess; and
forming, by dissolving part or all of the first sacrificing layer, a first function layer obtained by patterning the first functional material layer,
wherein a contour of the first recess includes a first recessed figure that is a recessed figure in a plan view from above.

2. The method for manufacturing a display device according to claim 1,
wherein A is larger than 1.1 times B, where A is a peripheral length of the first recessed figure and B is a peripheral length of a protruding figure surrounding the first recessed figure and having a minimum area.

3. The method for manufacturing a display device according to claim 1,
wherein the first recessed figure has an elongated shape,
an outer shape of the first recessed figure includes a first contour portion,
a first line segment connecting both ends of the first contour portion is parallel to a long axis of the first recessed figure, and
D is larger than 1.1 times E, where D is a length of the first contour portion and E is a length of the first line segment.

4. The method for manufacturing a display device according to claim 3,
wherein the first contour portion does not cross a center line parallel to the long axis of the first recessed figure.

5. The method for manufacturing a display device according to claim 3,
wherein the first contour portion includes a fractal structure.

6. The method for manufacturing a display device according to claim 3,
wherein a width in a direction along a short axis of the first recessed figure is regularly and repeatedly increased and decreased along the long axis of the first recessed figure.

7. The method for manufacturing a display device according to claim 1,
wherein the contour of the first recess is an edge between an upper face and a side face of the first sacrificing layer, and
the edge has an angular corner.

8. The method for manufacturing a display device according to claim 1,
wherein the first recessed figure has line symmetry or rotation symmetry.

9. The method for manufacturing a display device according to claim 1,
wherein in the forming the first recess, the first recess extends through the first sacrificing layer, and
in the forming the first function layer, all the first sacrificing layer is dissolved.

10. The method for manufacturing a display device according to claim 1,
wherein in the forming the first recess, a remaining portion of the first sacrificing layer remains below a bottom face of the first recess, and
in the forming the first function layer, a portion other than the remaining portion of the first sacrificing layer is dissolved, and thus the remaining portion of the first sacrificing layer remains.

11. (canceled)

12. The method for manufacturing a display device according to claim 1,
wherein the first functional material layer includes a particle having a particle diameter of 1 nm or more and 100 nm or less.

13. (canceled)

14. The method for manufacturing a display device according to claim 1, the method further comprising:
forming a second sacrificing layer;
forming a second recess in the second sacrificing layer;
forming a second functional material layer at least in the second recess; and
forming, by dissolving part or all of the second sacrificing layer, a second function layer obtained by patterning the second functional material layer,
wherein a contour of the second recess includes a second recessed figure in a plan view from above,
wherein a recessed portion of the first function layer faces a protruding portion of the second function layer in a plan view from above, and
a protruding portion of the first function layer faces a recessed portion of the second function layer in a plan view from above.

15. The method for manufacturing a display device according to claim 14,
wherein the first function layer and the second function layer are in contact with each other in a plan view from above.

16. (canceled)

17. The method for manufacturing a display device according to claim 1, the method further comprising:
forming a second sacrificing layer;
forming a second recess in the second sacrificing layer;
forming a second functional material layer at least in the second recess; and
forming, by dissolving part or all of the second sacrificing layer, a second function layer obtained by patterning the second functional material layer,
wherein a contour of the second recess includes a second recessed figure in a plan view from above,
wherein part of the first function layer and part of the second function layer overlap each other in a plan view from above.

18. (canceled)

19. (canceled)

20. A display device, comprising:
a first function layer formed in a light-emitting region and a non-light-emitting region that is a region other than the light-emitting region, a contour of the first function layer being formed in the non-light-emitting region in a plan view; and
a lower layer formed below the first function layer and overlapping the contour in a plan view,
wherein the contour includes a recessed figure in a plan view from above, and
at least part of an outer side face of the first function layer is separated from the lower layer.

21. The display device according to claim 20,
wherein the first function layer is formed with an angle between an outer side face and a lower face of the first function layer being 90 degrees or more.

22. The display device according to claim 20,
wherein the lower layer includes a planar face, and
the contour is formed on the planar face.

23. The display device according to claim 20,
wherein the lower layer is a charge transport layer.

24. The display device according to claim 20, comprising:
a first subpixel including the first function layer;
a second subpixel including a second function layer different from the first function layer; and
a third subpixel including a third function layer different from the first function layer and the second function layer,
wherein the first subpixel, the second subpixel, and the third subpixel each emit light in different colors.

25. The display device according to claim 24,
wherein the contour of the first function layer overlaps at least one of the second function layer or the third function layer in a plan view.

26. The display device according to claim 24,
wherein the first function layer is a red light-emitting layer,
the second function layer is a green light-emitting layer, and
the third function layer is a blue light-emitting layer.
